(19) United States
(12) Patent Application Publication
(10) Pub. No.: US 2007/0186846 A1
(43) Pub. Date: Aug. 16, 2007

(54) NON-SPHERICAL SEMICONDUCTOR NANOCRYSTALS AND METHODS OF MAKING THEM

(75) Inventors: Ken-Tye Yong, N. Tonawanda, NY (US); Yudhisthira Sahoo, Amherst, NY (US); Mark Swihart, Williamsville, NY (US); Paras Prasad, Williamsville, NY (US)

Correspondence Address: NIXON PEABODY LLP - PATENT GROUP, CLINTON SQUARE, P.O. BOX 31051, ROCHESTER, NY, 14603-1051, US

(73) Assignee: The Research Foundation of State University of New York, Amherst, NY (US)

(21) Appl. No.: 11/614,641

(22) Filed: Dec. 21, 2006

Related U.S. Application Data
(60) Provisional application No. 60/752,445, filed on Dec. 21, 2005.

(51) Int. Cl. C30B 13/00; C30B 19/00

(52) U.S. Cl. 117/41; 117/956; 117/958; 117/56; 977/731; 977/734; 977/824

(57) ABSTRACT

The present invention relates to a method of making non-spherical semiconductor nanocrystals. This method involves providing a reaction mixture containing a first precursor compound, a solvent, and a surfactant, where the first precursor compound has a Group II or a Group IV element and contacting the reaction mixture with a pure noble metal nanoparticle seed. The reaction mixture is heated. A second precursor compound having a Group VI element is added to the heated reaction mixture under conditions effective to produce non-spherical semiconductor nanocrystals. Non-spherical semiconductor nanocrystals and nanocrystal populations made by the above method are also disclosed.

This application claims the priority benefit of U.S. Provisional Patent Application Ser. No. 60/752,445, filed Dec. 21, 2005, which is hereby incorporated by reference in its entirety.

This work was supported in part by grant number F49620-01-1-0358 from the USAF/AFOSR. The U.S. Government may have certain rights.

### FIELD OF THE INVENTION

The present invention relates to methods of making non-spherical semiconductor nanocrystals and non-spherical semiconductor nanocrystals made by the methods.

### BACKGROUND OF THE INVENTION

Semiconductor nanocrystals have emerged as an important class of materials because of their tunable optoelectronic properties that arise from quantum size effects. They can be used as active components in functional nanocomposites (Morris et al., “Silica Sol as a Nanoglue: Flexible Synthesis of Composite Aerogels,” Science 284:622-624 (1999)), chemical sensors (Kong et al., “Nanotube Molecular Wires as Chemical Sensors,” Science 287:622-625 (2000)), biomedicine (Bruchez et al., “Semiconductor Nanocrystals as Fluorescent Biological Labels,” Science 281:2013-2016 (1998); Chan et al., “Quantum Dot Bioconjugates for Ultrasensitive Nonisotopic Detection,” Science 281:2016-2018 (1998); Taton et al., “Scanometric DNA Array Detection with Nanoparticle Probes,” Science 289:1757-1760 (2000)), optoelectronics (Huynh et al., “Hybrid Nanorod-Polymer Solar Cells,” Science 295:2425-2427 (2002); Klimov et al., “Optical Gain and Stimulated Emission in Nanocrystal Quantum Dots,” Science 290:314-317 (2000)), and nanoelectronics (Duan et al., “Indium Phosphide Nanowires as Building Blocks for Nanoscale Electronic and Optoelectronic Devices,” Nature 409:66-69 (2001); Fuhrer et al., “Crossed Nanotube Junctions,” Science 288:494-497 (2000); Gudiksen et al., “Growth of Nanowire Superlattice Structures for Nanoscale Photonics and Electronics,” Nature 415:617-620 (2002)). More recently, nanocrystals of different shapes including rods, bipods, tripods, tetrapods, and cubes (Burda et al., “Chemistry and Properties of Nanocrystals of Different Shapes,” Chem. Rev. 105:1025-1102 (2005)) have been fabricated. These non-spherical nanocrystals serve as ideal model systems for studying anisotropic optoelectronic effects, including polarized emission and quantum rod lasing. They may also serve as building blocks for complex nanostructures in nanoelectronics and nanomedicine.

The physical properties of semiconductor nanocrystals are strongly influenced by their size and shape (Prasad, Nanophotonics; Wiley-Interscience, New York (2004); Du et al., “Optical Properties of Colloidal PbSe Nanocrystals,” J. Nano Lett 2:1321-1324 (2002); Pietryga et al., “Pushing the Band Gap Envelope: Mid-Infrared Emitting Colloidal PbSe Quantum Dots,” J. Am. Chem. Soc. 126:11752-11753 (2004)). For the past two decades, a growing array of well-developed synthetic methodologies have been used to produce nearly monodispersed spherical nanocrystals, also called quantum dots. The physical properties of the quantum dots were explored extensively with regard to the effect of quantum confinement on their optical and electronic properties. Recently, the effects of nanocrystal shape have received great attention because unique behavior is expected in the evolution from zero-dimensional (0-D) quantum dots to one-dimensional (1-D) quantum rods or quantum wires (Kudera et al., “Selective Growth of PbSe On One or On Both Tips of Colloidal Semiconductor Nanorods,” Nano Lett 5:445-449 (2005); Peng et al., “Shape Control of CdSe Nanocrystals,” Nature 404:59-61 (2000); Burda et al., “Chemistry and Properties of Nanocrystals of Different Shapes,” Chem. Rev. 105:1025-1102 (2005)). For example, it was reported that CdSe quantum rods emitted light that was linearly polarized along the c-axis of the crystallites and that the degree of polarization was dependent on the aspect ratio of the nanocrystals (Peng et al., “Shape Control of CdSe Nanocrystals,” Nature 404:59-61 (2000)). It was also shown recently that magnetic quantum wires have higher blocking temperatures and magnetization than their quantum dot counterparts. These early studies of anisotropic nanocrystals show that nanostructures of different shapes (e.g. quantum rods and quantum wires) can offer new possibilities for tailoring material properties and offer improved performance when used as functional components in lasers or various other memory and optoelectronic devices (Huynh et al., “Hybrid Nanorod-Polymer Solar Cells,” Science 295:2425-2427 (2002)).

Template-free shape control during the growth of nanocrystals depends on the ability to achieve different growth rates on different crystal faces within the same nanocrystal. This occurs in an anisotropic crystal structure, such as the wurtzite structure of CdSe, when a single growth direction is favored over others. In this system, polymorphism is also possible, and a key parameter is the energy difference between different polymorphs (Manna et al., “Controlled Growth of Tetrapod Branched Inorganic Nanocrystals,” Nat Mater. 2:382-385 (2003)). In the case of CdSe and CdTe, nanocrystals may nucleate with the zincblende structure, followed by growth of the wurtzite structure (Peng, “Formation of High-Quality CdTe, CdSe, and CdS Nanocrystals Using CdO as Precursor,” J. Am. Chem. Soc. 123:183-184 (2001); Yu et al., “Experimental Determination of the Extinction Coefficient of CdTe, CdSe, and CdS Nanocrystals,” Chem. Mater. 15:2854-2860 (2003)) on these nuclei to produce tetrapods. The energy difference between the two crystal structures is small enough so that both are accessible at the typical reaction temperatures. This mechanism has been associated with the observation of kinetically promoted tetrapod structures of CdSe and CdTe (Manna et al., “Controlled Growth of Tetrapod Branched Inorganic Nanocrystals,” Nat Mater. 2:382-385 (2003); Manna et al., “Synthesis of Soluble and Processable Rod-, Arrow-, Teardrop-, and Tetrapod-Shaped CdSe Nanocrystals,” J. Am. Chem. Soc. 122:12700-12706 (2000)).

Generally, the colloidal growth of non-spherical nanocrystals is achieved by one of two methods. In one approach, the reaction is carried out in the presence of two surfactants with significantly different binding abilities to the nanocrystal faces, such as phosphonic acid and a long chain carboxylic acid or amine. The strongly-adsorbed phosphonic acid slows the growth of the nanocrystal and results in a preferential growth along the c-axis of the wurtzite structure. In this method, a high precursor concentration is maintained often via multiple injections of the precursors into the reaction pot during the growth of the nanocrystal. A mixture of carboxylic acid and amine without a phosphonic acid does not induce anisotropic nanocrystal growth, but yields spherical nanocrystals (Li et al., “Band Gap Variation of Size- and Shape-Controlled Colloidal CdSe Quantum Rods,” Nano Lett 1:349-351 (2001)). Another approach is the solution-liquid-solid (“SLS”) method, analogous to the vapor-liquid-solid (“VLS”) approach for growing nanowires from vapor precursors. This method uses metallic nanoparticles as seeds to promote anisotropic crystal growth (Kan et al., “Synthesis and Size-Dependent Properties of Zinc-Blende Semiconductor Quantum Rods,” Nat. Mater. 2:155-158 (2003)). The metallic seed particles melt, precursor atoms dissolve in them, and crystal growth occurs at the metal's liquefied surface. This provides a lower energy path to nucleation than homogeneous nucleation in the vapor or solution phase. Nanocrystal rods or wires of materials including InP (Nedeljkovic et al., “Growth of InP Nanostructures Via Reaction of Indium Droplets with Phosphide Ions: Synthesis of InP Quantum Rods and InP-TiO₂ Composites,” J. Am. Chem. Soc. 126:2632-2639 (2004)), InAs (Kan et al., “Shape Control of III V Semiconductor Nanocrystals: Synthesis and Properties of InAs Quantum Rods,” Faraday Discuss. 125:23-38 (2004)), and Si (Holmes et al., “Control of Thickness and Orientation of Solution-Grown Silicon Nanowires,” Science 287:14711473 (2000)) have been prepared using metallic nanoparticles as seeds. Growth of CdSe wires by the SLS method using bismuth-coated gold nanoparticles has been reported (Grebinski et al., “Solution Based Straight and Branched CdSe Banowires,” Chem. Mater. 16:5260-5272 (2004)), although those experiments were carried out using technical grade (90%) trioctylphospine oxide containing phosphonic acids that may also promote anisotropic growth (Peng et al., “Shape Control of CdSe Nanocrystals,” Nature 404:59-61 (2000)). The use of pure noble metal nanoparticles to aid the growth of non-spherical nanocrystals has not previously been demonstrated.

Growth of CdSe wires by SLS methods suffer various limitations. First, high cadmium precursor concentrations must be used. Second, the presence of trioctylphosphine oxide and phosponic acids are usually needed as the reaction solvent. Besides being a reaction solvent, phosphonic acids such as tetradecylphosphonic acid and octadecyl phosphonic acid are constantly used to form cadmium phosphonic acid complexes for the premixed precursor injection. The main aim of forming such complexes is to slow the growth of CdSe and prevent the formation of “large” CdSe clusters. Third, multiple injections of the premixed precursors into the reaction mixture over a long period of time are unavoidable such that growth of rods is facilitated.

Other groups have prepared CdSe quantum rods and multipods with both lower yield of material (in terms of the fraction of the precursors converted to rods and multipods) and lower quantum yield (photoluminescence efficiency). In those cases, they have used the following reaction conditions: 1) high reagent concentration, 2) multiple injections of mixed precursors, 3) high reaction temperature, 4) time-consuming operation, and 5) highly toxic and expensive reagents such as dimethyl cadmium.

The present invention is directed to overcoming these and other limitations in the art.

### SUMMARY OF THE INVENTION

One aspect of the present invention is directed to a method of making non-spherical semiconductor nanocrystals. This method involves providing a reaction mixture containing a first precursor compound, a solvent, and a surfactant, where the first precursor compound has a Group II or a Group IV element, and contacting the reaction mixture with a pure noble metal nanoparticle seed. The reaction mixture is heated. A second precursor compound containing a Group VI element is added to the heated reaction mixture under conditions effective to produce non-spherical semiconductor nanocrystals.

Another aspect of the present invention is directed to a population of semiconductor nanocrystals containing at least about 90% non-spherical nanocrystals.

The method of the present invention has been optimized to produce high quantum-yield semiconductor nanocrystal rods and multipods in relatively large quantities and with desirable optoelectronic properties. The method of the present invention produces high chemical yields of the rod and multipod structures and high photoluminescence quantum yield. Reports in the scientific literature describe a general method for producing low quantum yield non-spherical semiconductor nanocrystals by using higher precursor concentrations and subsequently injecting the precursors into the reaction pot. Those methods require long hours of preparation. In contrast, the method of the present invention primarily addresses a facile one-pot synthesis approach to produce semiconductor nanocrystals of various aspect ratios with tunable optical properties by using noble metal nanoparticles as seeding agents. The aspect ratio of the nanocrystals can be easily tuned from ˜2 to ˜12. The high yield production and stability of high quantum yield of non-spherical semiconductor nanocrystals of the present invention will allow them to be used in applications in hybrid polymer solar cells, biological labeling, and other optoelectronics applications where high concentrations of highly stable nanocrystals are needed.

The method of the present invention also has the advantages of producing higher quality nanocrystals, indicated by the higher photoluminescence quantum yield which generally occurs due to good crystallinity and minimal surface trap states or crystal defects. Compared to the prevalent literature methods, these nanocrystals are made from less expensive and less toxic precursors, and from a simpler procedure. In accordance with the present invention, nonspherical nanocrystals can be obtained through a one-pot synthesis method without the use of phosphonic acids or trioctylphosphine oxide, the surfactants most often used for anisotropic growth of nanocrystals. The method of the present invention also does not require multiple precursor injections. The reaction temperature and reagent concentrations used in the method of the present invention are much lower than the ranges previously reported for non-spherical semiconductor nanocrystal synthesis, which are as high as 0.5-0.8 mmol per ml reaction mixture. The noble metal seed particles employed in the present inventive method facilitate nucleation and growth of nanocrystals at relatively mild conditions. The process is fast and can be finished within about 3 hours.

### BRIEF DESCRIPTION OF THE DRAWINGS

FIGS. 1A-B are schematic models of CdSe quantum rod and tripod nanocrystal growth on a gold nanoparticle according to one embodiment of the method of the present invention. In FIG. 1A, a hetero-tripod with CdSe basal planes is aligned with the planes of the gold nanoparticle. These can be brought into rough epitaxial registration over a distance comparable to the rod diameter. In FIG. 1B, nucleation of a zincblende fragment on the surface of Au nanoparticles is followed by growth of wurtzite arms to form a homo-tripod.

FIGS. 2A-D are photographs of noble metal nanoparticles prepared using a two-phase synthesis. The nanoparticles include gold (Au) (FIG. 2A), silver (Ag) (FIG. 2B), palladium (Pd) (FIG. 2C), and platinum (Pt) (FIG. 2D) nanoparticles, which were prepared using a hot colloidal synthesis. The average diameter of Au, Ag, Pd, and Pt nanoparticles is 4.1, 7.0, 2.7, and 8.5 nm, respectively. The scale bars in the photographs of FIGS. 2A-D are 25 nm.

FIG. 3 is a photograph of quantum dots obtained in the absence of metallic nanoparticles. Myristic acid and hexadecylamine were used as the capping agents. The quantum dots have an average size of 3.9±0.1 nm. In contrast to surfactant mixtures that include phosphonic acids, the mixture of myristic acid and hexadecylamine does not induce anisotropic growth.

FIG. 4 is a photograph of CdSe(Pt) nanocrystals obtained at 3 minutes reaction time pursuant to one embodiment of the method of the present invention. More than 95% of the population is quantum rods. The average length and diameter of the quantum rods are 10.6±2.5 nm and 2.9±0.3 nm, respectively.

FIGS. 5A-F are High Resolution Transmission Electron Microscopy (“HRTEM”) images of multiple CdSe quantum rods growing from a single Au nanoparticle pursuant to one embodiment of the method of the present invention. In FIG. 5B, a single CdSe quantum rod is shown growing out of an Au nanoparticle (hetero-multipod) with the CdSe quantum rod having a latticle spacing of 3.5 Å. In FIGS. 5C-E, seeded growth of CdSe quantum rods and bipods is shown. In FIG. 5F, a single CdSe quantum rod seeded growth with Au nanoparticles is shown.

FIGS. 6A-F are Transmission Electron Microscope (“TEM”) images of bipod, tripod, and tetrapod semiconductor nanocrystals obtained after a short reaction time (ca. 3 min) in the presence of Au (FIG. 6A), Ag (FIG. 6B), Pd (FIG. 6C), and Pt (FIG. 6D) nanoparticles. FIGS. 6E-F are HRTEM images of a single CdSe quantum rod growing out of a gold nanoparticle (heteromultipod) and a pure CdSe tripod (homomultipod) with a lattice spacing of 3.5 Å.

FIGS. 7A-D are TEM images of quantum rods synthesized using gold (FIG. 7A), silver (FIG. 7B), palladium (FIG. 7C), and platinum (FIG. 7D) nanoparticles as seeds. Less than 2% of the rods have branched structures.

FIG. 8 is a photograph of CdSe nanocrystals obtained using Au nanoparticles as seeds (“CdSe(Au)”) where the sample was washed with acetone and redispersed in hexane, but seed particles were not separated from the nanorods. It is evident that the Au nanoparticles only serve as seeds and are not incorporated into the final rods. Metal nanoparticles can easily be separated from CdSe nanocrystals by dispersing the mixture in hexane and centrifuging.

FIG. 9 is a graph illustrating the structural characterization of CdSe(Au) rods using powder x-ray diffraction of CdSe(Au) rods. The (002) peak identified in FIG. 9 is narrower and more intense than other peaks due to the extended domain along the c-axis of the rod.

FIGS. 10A-B are graphs showing absorption and emission spectra from CdSe multipods (FIG. 10A) and quantum rods (FIG. 10B) synthesized using gold (1), silver (2), palladium (3), and platinum (4) nanoparticles according to various embodiments of the method of the present invention. In FIG. 10A there is a very low population of CdSe(Pt) multipods and, therefore, no absorption/PL is presented for those multipods.

FIG. 11 is a TEM image of PbSe nanocrystals prepared in the absence of metal nanoparticles. The scale bar is 70 nm. The average length and width of these PbSe nanocrystals are 13.1 and 8.75 nm, respectively.

FIGS. 12A-C are images of PbSe quantum rods produced according to one embodiment of the method of the present invention. FIG. 12A is a TEM image of PbSe quantum rods showing that they are highly monodisperse and that more than 90% of the particles are rods. The average length and width of the quantum rods are 38.7 and 10.3 nm, respectively. FIG. 12B is an HRTEM image of PbSe quantum rods with lattice fringes of 3.1 Å. FIG. 12C is the corresponding Fast Fourier Transform (“FFT”) image from the rod shown in FIG. 12B.

FIGS. 13A-H are TEM images of PbSe nanocrystals synthesized with Au nanoparticles under different conditions. FIGS. 13A-C are images of PbSe quantum rods synthesized with ˜0.0005 mmol of Au nanoparticles. The growth time increases from FIG. 13A to FIG. 13C. FIG. 13D is an image of cross-shaped PbSe nanocrystals synthesized with ˜0.005 mmol Au nanoparticles. FIG. 13E is an image of Au/PbSe core/shell structure synthesized with ˜0.025 mmol Au nanoparticles. FIG. 13F is an image of T-shape PbSe nanocrystals obtained at a Pb:Se ratio of 1:2 with ˜0.0005 mmol of Au nanoparticles. FIG. 13G is an image of cube-like PbSe nanocrystals synthesized at a Pb:Se ratio of 2:1 with ˜0.0005 mmol of Au nanoparticles. FIG. 13H is an image of PbSe quantum dots synthesized at a Pb:Se ratio of 3:1 with ˜0.0005 mmol of Au nanoparticles. The scale bar in FIGS. 13A-H is 70 nm.

FIG. 14 is an HRTEM image of core-shell gold-PbSe nanocrystals produced using ˜0.025 mmol gold nanoparticle seeds according to one embodiment of the method of the present invention.

FIG. 15 is an electron diffractogram of core-shell gold-PbSe nanocrystals synthesized according to one embodiment of the method of the present invention. The rings shown in FIG. 15 index well to the cubic rock-salt structure of PbSe.

FIG. 16 is a powder x-ray diffraction (“XRD”) pattern of PbSe quantum rods like those shown in FIGS. 12A-C.

FIGS. 17A-E are TEM images of PbSe nanocrystals synthesized, according to one embodiment of the present invention, with Ag nanoparticles under different conditions. FIG. 17A is a TEM image of diamond-like PbSe nanocrystals synthesized with ˜0.0005 mmol of Ag nanoparticles. FIGS. B-E are TEM images of multi-branch-shaped PbSe nanocrystals synthesized with ˜0.025 mmol Ag nanoparticles. The scale bars in FIGS. 17A-E are 70 nm.

FIGS. 18A-B are TEM images of PbSe nanocrystals synthesized, in accordance with one embodiment of the method of the present invention, with Pd nanoparticles. FIG. 18A is a TEM image of star-like PbSe nanocrystals synthesized with ˜0.0005 mmol of Pd nanoparticles. FIG. 18B is a TEM image of quasi-spherical PbSe nanocrystals synthesized with ˜0.025 mmol. The scale bars in FIGS. 18A-B are 70 nm.

FIGS. 19A-D are HRTEM images of different PbSe nanocrystals synthesized with Au, Ag, and Pd nanoparticles. FIG. 19A is a TEM image of L- and T-shaped PbSe nanocrystals corresponding to FIG. 13F. FIG. 19B is a TEM image of multi-branched PbSe nanocrystals corresponding to FIGS. 17B-E. FIG. 19C is a TEM image of diamond-shaped PbSe nanocrystals corresponding to FIG. 17A. FIG. 19D is a TEM image of star-shaped PbSe nanocrystals corresponding to FIG. 18A. Insets give the Fourier transforms of the nanocrystal just to the left of the inset (FIG. 19A), the upper-left portion of the branched nanocrystal to the left of the inset (FIG. 19B), the nanocrystal just below the inset (FIG. 19C), and the nanocrystal in the upper left (FIG. 19D).

FIG. 20 is a graph showing photocurrent (circles) and dark current (squares) as a function of applied voltage in a PbSe nanorods/PVK composite device at the infrared wavelength of 1.34 μm. The inset shows a schematic of the sandwich nanocomposite device structure.

### DETAILED DESCRIPTION OF THE INVENTION

One aspect of the present invention is directed to a method of making non-spherical semiconductor nanocrystals. This method involves providing a reaction mixture containing a first precursor compound, a solvent, and a surfactant, where the first precursor compound has a Group II or a Group IV element, and contacting the reaction mixture with a pure noble metal nanoparticle seed. The reaction mixture is heated. A second precursor compound containing a Group VI element is added to the heated reaction mixture under conditions effective to produce non-spherical semiconductor nanocrystals.

A suitable reaction mixture for carrying out the method of the present invention contains a first precursor compound, a solvent, and a surfactant. The first precursor compound has either a Group II or a Group IV element. As used herein, a Group II element is any element belonging to Group II of the periodic table. Particularly suitable Group II elements include, without limitation, cadmium and zinc. Group IV elements refer to any element belonging to Group IV of the periodic table. In a preferred embodiment, the Group IV element is lead.

The first precursor compound may be present in the reaction mixture in a concentration of between about 0.06-0.2 mmol per ml reaction mixture. In one embodiment, a first precursor compound containing a Group II element is preferably present in the reaction mixture at the lower end of this concentration range, while a first precursor compound containing a Group IV element is preferably present in the reaction mixture at the higher end of this concentration range.

In a preferred embodiment of the method of the present invention, the first precursor compound is cadmium oxide (Group II) or lead oxide (Group IV).

Suitable solvents of the reaction mixture may include a variety of widely known solvents. A preferred solvent of the reaction mixture is phenyl ether.

The surfactant of the reaction mixture may vary depending on whether the first precursor compound has a Group II or a Group IV element. When a Group II element is employed in the first precursor compound, a particularly preferred surfactant is myristic acid, a member of the long chain fatty acids. It is found that the size distribution of spherical nanocrystals appears very uniform when myristic acid is employed. Another preferred surfactant ubiquitously used is trioctylphosphineoxide. When a Group IV element is employed in the first precursor compound, a particularly preferred surfactant is oleic acid. Other surfactants may include, without limitation, members of the fatty acids such as lauric acid, myristic acid, stearic acid, etc.

In carrying out the method of the present invention, the reaction mixture is contacted with a pure noble metal nanoparticle seed. The pure noble metal nanoparticles are used as seeding agents to aid anisotropic growth of semiconductor nanocrystals pursuant to the method of the present invention. Suitable metal nanoparticles include gold, silver, palladium, and platinum. One criterion for choosing a suitable metal nanoparticle is the boiling point lowering of the particle of the material corresponding its bulk state. The size of the metal nanoparticles may vary, but preferred nanoparticles are 2-6 nm in size. Gold, silver, and palladium nanoparticles can be prepared by a two-phase method (Brust et al., “Synthesis of Thiol-Derivatised Gold Nanoparticles in a Two-Phase Liquid Liquid System,” J. Chem. Soc. Chem. Commun. 801 (1994); Leff et al., “Thermodynamic Control of Gold Nanocrystal. Size, Experiment and Theory,” J. Phys. Chem. 99:7036-7041 (1995); Leff et al., “Synthesis and Characterization of Hydrophobic, Organically-Soluble Gold Nanocrystals Functionalized with Primary Amines,” Langmuir 12:4723-4730 (1996), which are hereby incorporated by reference in their entirety). Platinum nanoparticles can be prepared by a hot colloidal synthesis method described infra.

The heating step of the method of the present invention is preferably carried out to a temperature below that at which the noble metal nanoparticle seed melts. However, the heating step may be carried out to a temperature at which the noble metal nanoparticle seed has a quasi-molten surface layer. The preferred temperature to which the reaction mixture is heated may depend upon the reagents in the reaction mixture. For example, when a first precursor compound having a Group II element is employed, the heating step is preferably carried out to a temperature no higher than about 260° C. or, more preferably, no higher than about 225° C. A preferred temperature range to which the reaction mixture is heated when a first precursor compound having a Group II element is employed is about 200-260° C. On the other hand, when a first precursor compound having a Group IV element is employed, the heating step is preferably carried out to a temperature of no higher than about 170° C. or, more preferably, no higher than about 150° C. A preferred temperature range to which the reaction mixture is heated when a first precursor compound having a Group IV element is employed is about 130-170° C.

The heating step can be carried out under an argon atmosphere, although other methods may also be used. In a typical reaction, heating is carried out under an argon atmosphere for about 20 minutes, though the time of heating may vary depending on the particular reagents and conditions employed. It may also be desirable to maintain the reaction mixture at the elevated temperature for a period of time (i.e., 10-30 minutes).

After the reaction mixture is heated to the desirable temperature and maintained at that temperature for the desired time, a second precursor compound is added to the heated reaction mixture under conditions effective to produce non-spherical semiconductor nanocrystals. The second precursor compound has a Group VI element. As used herein, a Group VI element refers to any element belonging to Group VI of the periodic table. Particularly suitable Group VI elements include, without limitation, selenium and sulfur. In a preferred embodiment, the Group VI element is selenium.

A particularly preferred second precursor compound is trioctylphosphine selenide, although other Group VI-containing precursor compounds may also be used, such as tributylphosphine selenide.

The method of the present invention may further involve a step of quenching the heated reaction mixture after said adding step. Suitable quenching solutions include, without limitation, hexane and toluene, preferably maintained at room temperature. Other solutions widely known to those of ordinary skill in the art may also be used to quench the heated reaction mixture and include, without limitation, cyclohexane, octane, benzyl ether, octylether, etc.

The method of the present invention may also involve a washing and precipitating step after the quenching step. Suitable wash and precipitation conditions involve the addition of ethanol and centrifugation to the quenched non-spherical semiconductor nanocrystals. If desired, precipitated nanocrystals may be redispersed in various organic solvents (e.g., hexane, toluene, and chloroform) to form a stable dispersion.

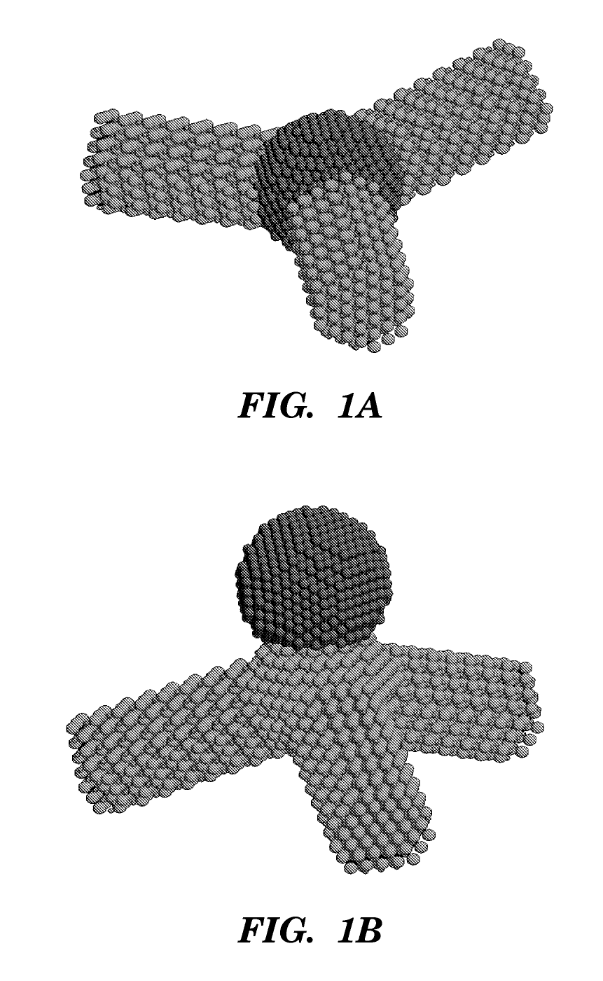

Nanocrystals produced by the method of the present invention can occur in various shapes, including, without limitation, quantum rods and multipods (i.e. bipods, tripods, and tetrapods). Multipods may occur both as simple homogeneous multipods and as heteromultipods with the metal nanoparticle at the center of the structure, as shown schematically in FIGS. 1A-B. The shape and size of the nanocrystals strongly depend on the concentration and the type of the noble metal nanoparticles, and on the ratio of first precursor compound to second precursor compound in the growth solution. Another factor contributing to the shape and size of nanocrystals made according to the method of the present invention is the length of the reaction time (i.e., the time in which the second precursor compound is reacted in the heated reaction mixture prior to a quenching step). Thus, by adjusting these and other factors, one can adjust the size and shape of nanocrystals made by the method of the present invention.

Another aspect of the present invention is directed to a population of semiconductor nanocrystals containing at least about 90% non-spherical nanocrystals.

The population of semiconductor nanocrystals may contain nanocrystals of various non-spherical shapes such as rods, multipods, T-shaped, multi-branched, diamond-shaped, and star-shaped nanocrystals, or mixtures thereof Other non-spherical shapes may also be present in the population of semiconductor nanocrystals. As described herein, desired shapes may be achieved, according to one embodiment of the present invention, by adjusting various parameters of the methods of the present invention.

The population of semiconductor nanocrystals of the present invention has a photoluminescence quantum yield value of at least about 8% or, more preferably, at least about 9, 10, or 11%. The photoluminescence quantum yield signifies the number of photons emitted per unit absorbed photons, which is a measure of the photoluminescence brightness of a population. This is measured as standard photoluminescent dye active in the relevant spectral region.

The population of semiconductor nanocrystals of the present invention may contain non-spherical nanocrystals having an aspect ratio value of about 2 to about 12, although other aspect ratio values can also be achieved. The aspect ratio is the ratio between the length (the longest dimension) and diameter (the shortest dimension) of a non-spherical nanocrystal, where a spherical nanocrystal is said to have an aspect ratio of one.

The population of semiconductor nanocrystals of the present invention contains at least about 80, 85, or 90% non-spherical nanocrystals. In a preferred embodiment, the population of non-spherical nanocrystals contains at least about 91%, 92%, 93%, 94%, 95%, 96%, 97%, 98%, or 99% non-spherical nanocrystals.

Non-spherical semiconductor nanocrystals of the present invention are useful in applications ranging from physics to medicine. While quantum dots have great promise as optical probes due to the fact that they are brighter than traditional organic chromophores, are resistant to photobleaching, have narrow and size-tunable emission wavelength, and have broad excitation spectra, non-spherical semiconductor nanocrystals render unique behavior, which make them useful for novel functional probes for biological and medicinal applications. For example, color control is achievable with non-spherical nanocrystals by tuning rod diameters, which govern the band gap energy of nanocrystal rods. Nanocrystal rods are also brighter single molecule probes as compared to quantum dots. Furthermore, nanocrystal rods show photoluminescence that is linearly polarized along the c-axis of the crystallites and a degree of polarization that is dependent on the aspect ratio of the nanocrystal. These unique characteristics of non-spherical nanocrystals render them useful for many sensitive imaging strategies as biological markers. Non-spherical nanocrystals are also superior components in photodetector and photovoltaic devices, because of improved charge transfers. The non-spherical semiconductor nanocrystals of the present invention are useful in these and other applications.

### EXAMPLES

The examples below are intended to exemplify the practice of the present invention but are by no means intended to limit the scope thereof

Examples 1-5 are directed to the synthesis of CdSe (Group II-VI) nanocrystals, and Examples 6-8 are directed to the synthesis of PbSe (Group IV-VI) nanocrystals.

### Example 1

### Materials

Cadmium oxide, myristic acid, 1-hexadecylamine, phenyl ether (99%), selenium, trioctylphosphine, tetraoctylammonium bromide (98%) (“TOAB”), hydrogen tetrachloroaurate(III) trihydrate (HAuCl₄.3H₂O), palladium chloride (PdCl₂), sodium borohydride, dodecylamine, and phenyl ether were purchased from Sigma-Aldrich (St. Louis, Mo.). Silver nitrate (AgNO₃) was purchased from Alfa Aesar (Ward Hill, Mass.). All chemicals were used as received. All solvents (hexane, toluene, and acetone) were used without any further purification.

### Example 2

### Synthesis of Au, Ag, Pd, and Pt Nanoparticles

Au Nanoparticles

20 mL of a bright yellow 5 mM HAuCl₄ solution was mixed with 10 mL of a 25 mM TOAB solution. The mixture was vigorously stirred for 15 minutes. An immediate two-layer separation occurred, with an orange/red organic phase on top and a clear to slightly orange tinted aqueous phase on the bottom. The organic phase was separated into a glass vial and to it was added 5 mL of a 0. 12 g of dodecylamine in toluene solution, followed by dropwise addition of 5 mL of a 0.1 M of sodium borohydride solution to the stirring reaction mixture. An instant color change of the organic phase was observed from an orange-red to a deep-red color. The stirring was continued for 30 minutes. Following this, the organic phase containing gold nanoparticles was separated from the aqueous phase, and the organic phase was adjusted to 20 mL by adding additional toluene. In general, these particles were extremely soluble in toluene, chloroform, and tetrahydrofuran and could be repeatedly precipitated and redissolved.

Ag Nanoparticles

In a procedure similar to the synthesis of Au nanoparticles described above, 10 mL of 25 mM TOAB solution was mixed with 20 mL of 5 mM AgNO₃. After vigorously stirring the mixture, two phases formed with a transparent organic phase on top and a “cloudy turbid” aqueous phase at the bottom. Upon adding sodium borohydride into the mixture, an instantaneous color change of the organic phase was observed from colorless to yellowish, then from yellowish to a greenish color.

Pd Nanoparticles

Pd nanoparticles were obtained by following a similar procedure as described above for the synthesis of Ag nanoparticles. 20 mL of 5 mM H₂PdCl₄ solution was mixed with 10 mL of 25 mM TOAB. After rapidly stirring the mixture, a two-layer separation occurred, with an orange/yellow organic phase on top and the clear aqueous phase on the bottom. Upon adding sodium borohydride into the mixture, an instant color change was observed, from colorless to a blackish color.

Pt Nanoparticles

Pt nanoparticles were synthesized via a hot colloidal synthesis method. Platinum(II) acetylacetonate (1 mmol), 1-2 hexadecanediol (5 mmol), oleyamine (1 mmol) and 10 ml phenyl ether were loaded into a 250 ml three necked reaction flask. The reaction mixture was slowly heated under argon atmosphere to 220° C. for 1 hour. After the reaction time was finished, the heating mantle was removed quickly and the reaction mixture was air-cooled to room temperature. The Pt colloidal solution displayed a blackish color. The Pt colloid was washed and precipitated two times with acetone. The resulting precipitate was then redissolved in 20 ml of toluene.

### Example 3

### Synthesis of CdSe Quantum Rods and Multipods

The following protocol was found to be optimal for obtaining CdSe quantum rods and multipods. 1 mmol cadmium oxide, 3 mmol myristic acid, 1 mmol hexadecylamine, and 15 ml phenyl ether were added into a 250 ml three-necked flask. 10 ml of freshly prepared metal nanoparticles (˜0.05 mmol metal atoms) in toluene was added. The reaction mixture was slowly heated under an argon atmosphere to 220° C., with a needle outlet that allowed the toluene to evaporate. After 20 minutes of heating, the needle was removed. The reaction mixture was maintained at 220° C. for another 20 minutes, then 0.5 ml of 1 M TOP-Se (0.5 mmol Se in 1.1 mmol trioctylphosphine) was rapidly injected. Approximately 1 ml aliquots were withdrawn after various reaction times. The aliquots were quenched with about 10 mL hexane. CdSe multipods and quantum rods were obtained at 1-3 minutes and 15-20 minutes, respectively.

### Example 4

### Separation of CdSe Quantum Rods and Multipods from Metallic Nanoparticles

The resulting sample was washed and precipitated twice by addition of acetone followed by centrifugation at 14000 rpm (12230 g) for 20 minutes to remove the reaction solvent and excess surfactants. The precipitate was then redispersed in hexane and centrifuged at 14000 rpm for 20 minutes. The supernatant contained the quantum rods, bipods, tripods, and/or tetrapods. The precipitate mainly contained metallic nanoparticles.

### Example 5

### Characterization of CdSe Nanocrystals

UV-Visible Absorbance

Absorption spectra were collected using a Shimadzu model 3101PC UV-Vis-NIR scanning spectrophotometer. Samples were measured against hexane as a reference. All samples were dispersed in hexane and loaded into a quartz cell for measurements.

Photoluminescence (PL) Spectroscopy

Emission spectra were collected using a Fluorolog-3 Spectrofluorometer (Jobin Yvon; fluorescence spectra). All samples were dispersed in hexane and loaded into a quartz cell for measurements. Fluorescence quantum yields of the CdSe nanocrystals in hexane solutions were determined by comparing the integrated emission from the nanocrystals to Coumarin 540A dye solutions of matched absorbance. Samples were diluted so that they were optically thin.

Transmission Electron Microscopy

Transmission Electron Microscopy images were obtained using a JEOL model JEM-100CX microscope with an acceleration voltage of 80 kV.

High-Resolution Transmission Electron Microscopy

High Resolution Transmission Electron Microscopy images were obtained with a model 200 JEOL microscope at an acceleration voltage of 200 kV.

X-Ray Diffraction

X-ray powder diffraction patterns were recorded using an X-ray diffraction with Cu Kα radiation. A concentrated nanocrystal dispersion was drop cast on a quartz plate for measurement.

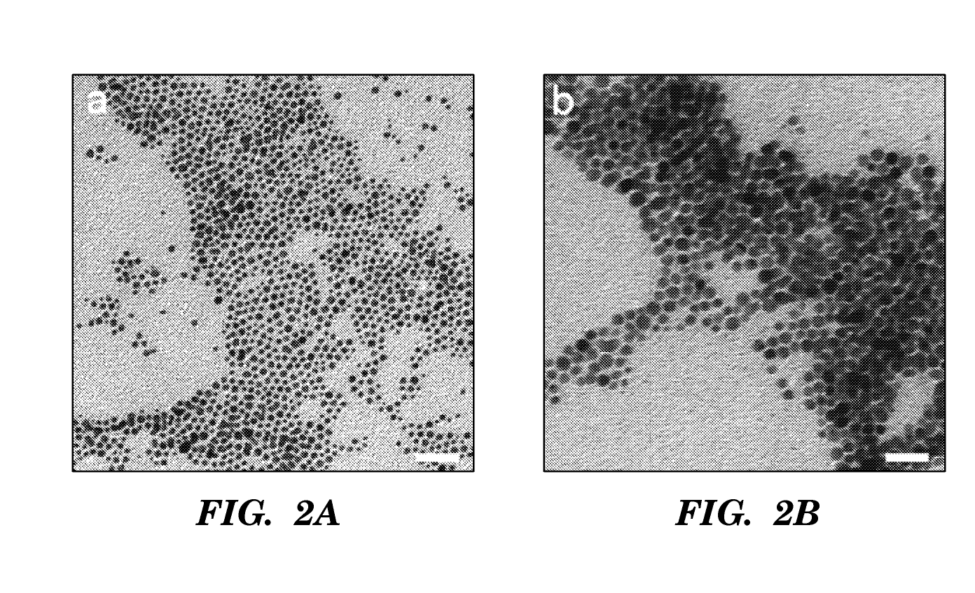

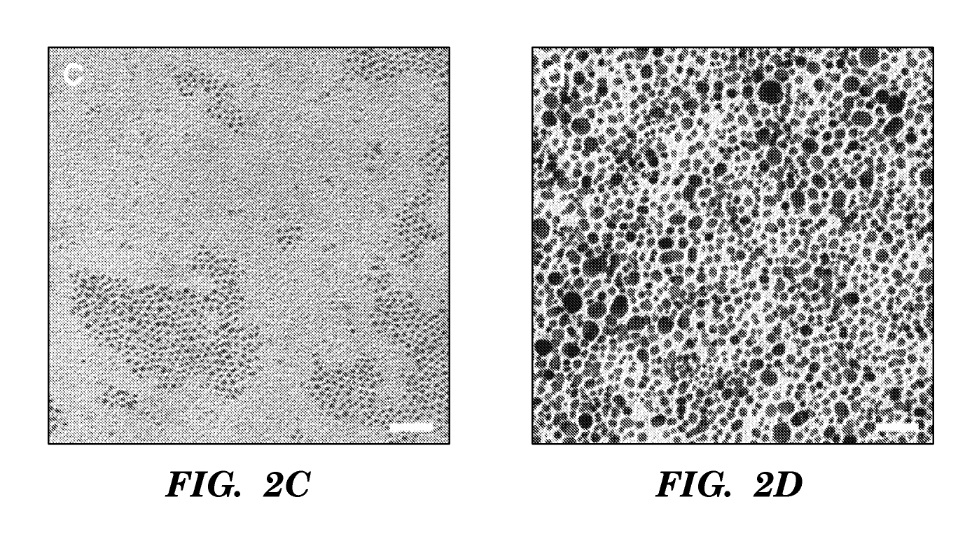

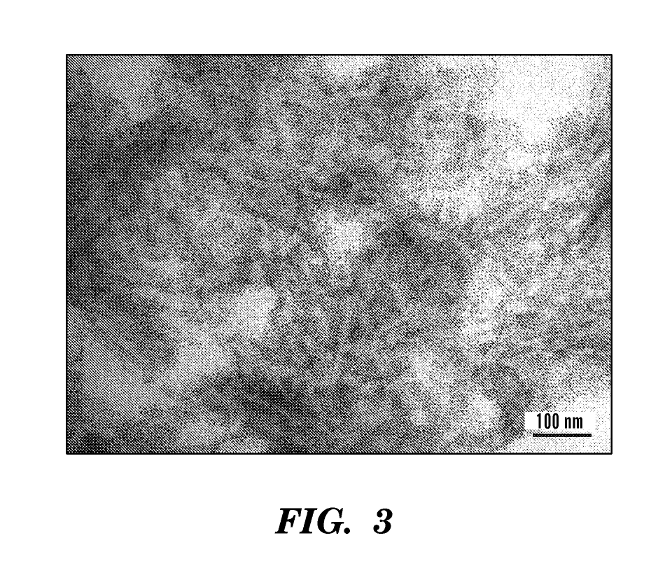

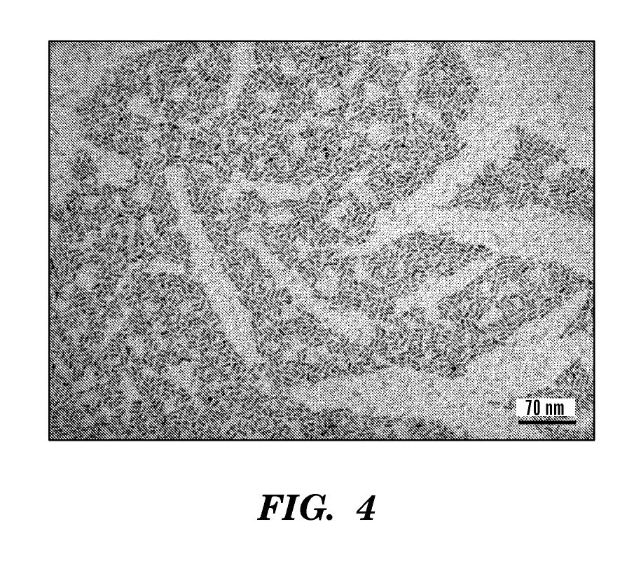

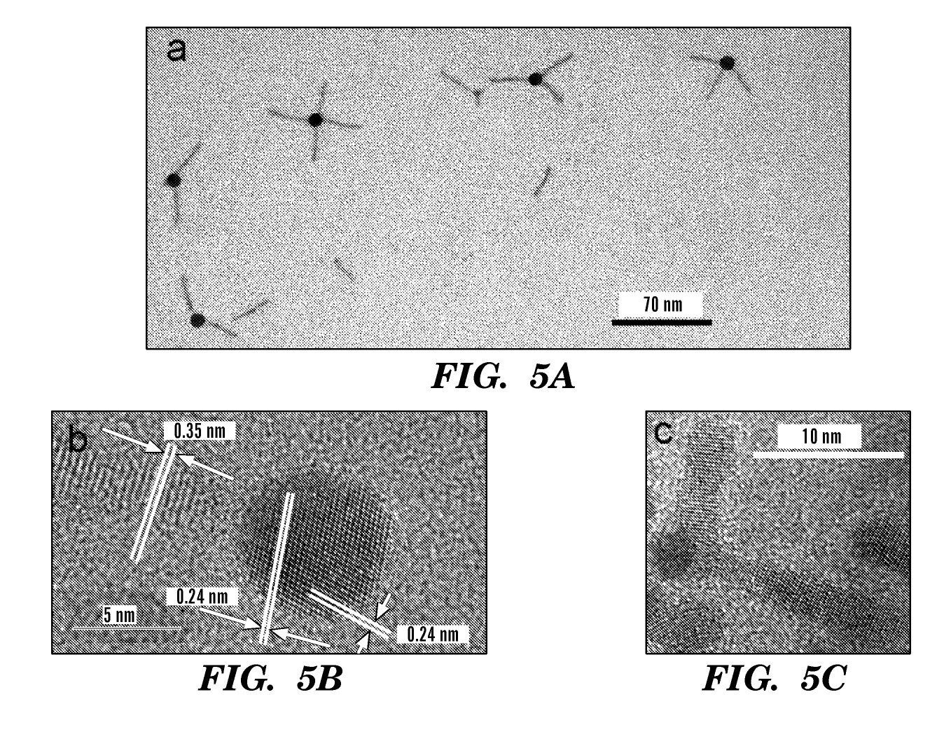

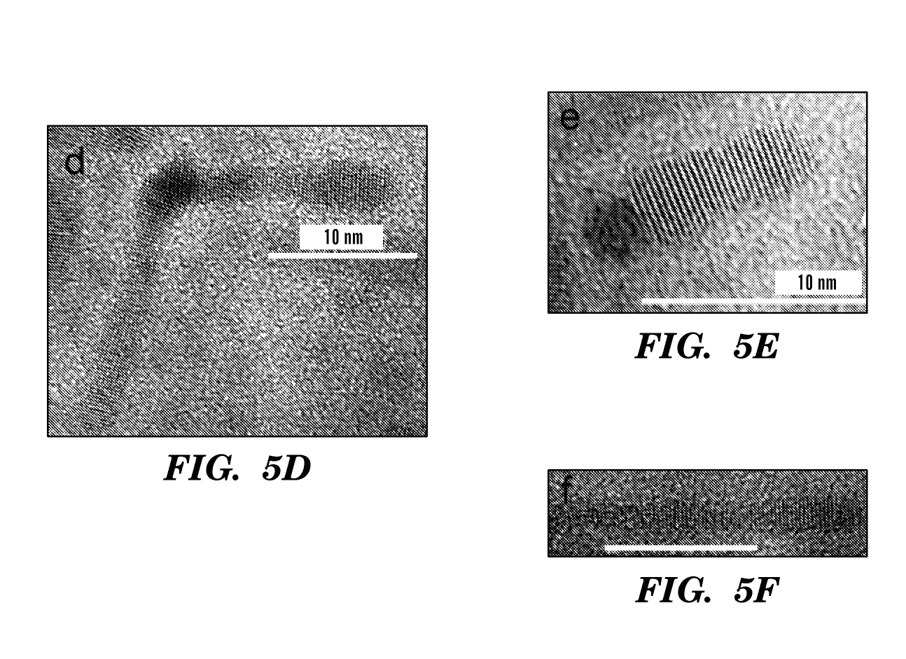

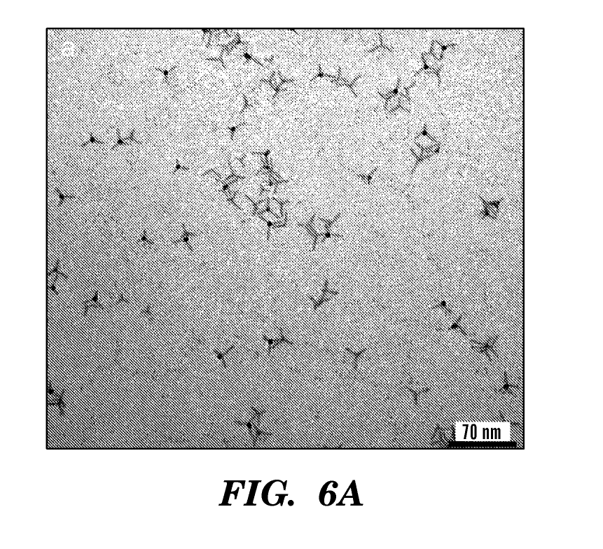

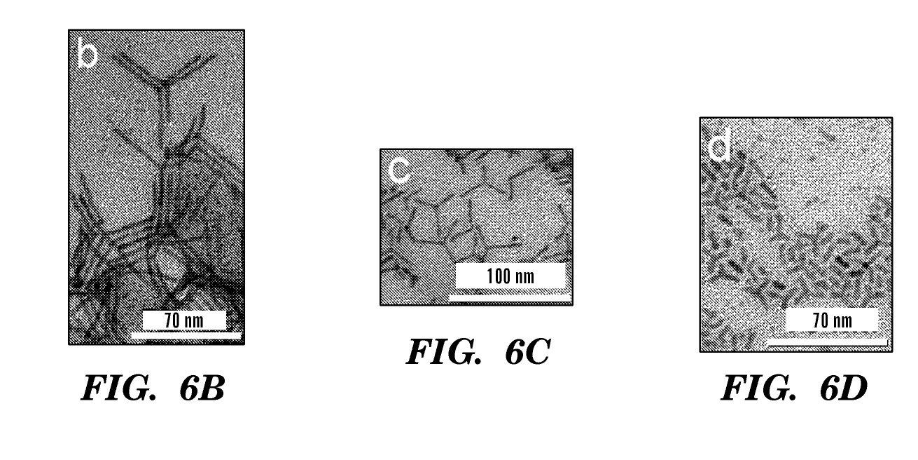

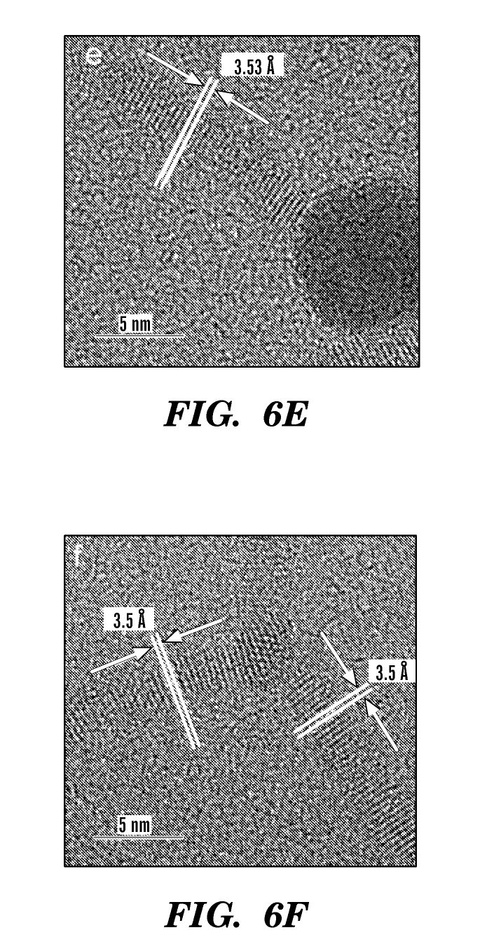

From TEM image analysis, the estimated sizes of the Au, Ag, Pd, and Pt seed nanoparticles were 4.1±1.2, 7±1.1, 2.7±1.4, and 8.5÷6.5 nm, respectively (FIGS. 2A-D). In the presence of any of these nanoparticles, the CdSe nanocrystals were obtained as multipods (bipods, tripods, and/or tetrapods), and rods. Under exactly the same conditions, but without the metal nanoparticles, only spherical CdSe nanocrystals were obtained (FIG. 3). The size and shape of the CdSe nanocrystals depended upon the choice of the metallic nanoparticle and the reaction time. CdSe nanocrystals seeded with Au, Ag, Pd, and Pt nanoparticles are referred to herein as CdSe(Au), CdSe(Ag), CdSe(Pd), and CdSe(Pt), respectively. CdSe(Au), CdSe(Ag), and CdSe(Pd) samples withdrawn during the first three minutes of reaction contained more multipod structures than rods (˜70% multipods), while the CdSe(Pt) samples always contained less than 5% multipods (FIG. 4). FIGS. 6A-D show TEM images of multipods produced at short reaction times using Au, Ag, Pd, and Pt nanoparticles as seeds, respectively (additional images are shown in FIGS. 5A-E). When Au seeds are used, an Au particle is sometimes present at the center of the multipod structure (a hetero-multipod) although homo-multipods constitute the dominant population (as shown for CdSe(Au) in FIG. 6A). However, homo-multipods are the only multipods observed in other cases. For a given multipod, the arm lengths are nearly equal. For several repeated syntheses conducted for CdSe(Au), it was observed that most of the anisotropic growth took place during the first two to three minutes immediately after injection. The initial population of the multipods decreased and that of the rods increased significantly as the reaction progressed. After 20 minutes, the population was ˜98% rods. The rod diameters were quite uniform (˜10% standard deviation in diameter, Table 1), whereas the rod length distribution was broader (standard deviation of 20% or more, Table 1). The rod diameter and length distribution were not simply correlated to the seed particle composition, size, or polydispersity. Most notably, in the case of the highly polydispersed Pt nanocrystals, the multipods and rods retained fairly uniform rod diameters and lengths.

TABLE 1
Size statistics for quantum rods.

| | Size of | | | | | |
|---|---|---|---|---|---|---|
| Type of | metal nano- | CdSe Rod | CdSe Rod | | Reaction | Shape of |
| metal nano- | particles | Length | Diameter | Aspect | Time | Nano- |
| particles | (nm) | (nm) | (nm) | Ratio | (minutes) | crystals |
| Gold | 4.1 ± 1.2 | 33.0 ± 6.0 | 2.7 ± 0.3 | 12.2 | 20 | Rod |
| Silver | 7 ± 1.1 | 30.0 ± 6.7 | 3.0 ± 0.3 | 10.0 | 20 | Rod |
| Palladium | 2.7 ± 1.4 | 20.0 ± 5.2 | 3.4 ± 0.4 | 5.8 | 20 | Rod |
| Platinum | 8.5 ± 6.5 | 8.0 ± 4.7 | 3.5 ± 0.3 | 2.2 | 20 | Rod |
| none | — | — | — | — | 20 | Dot |

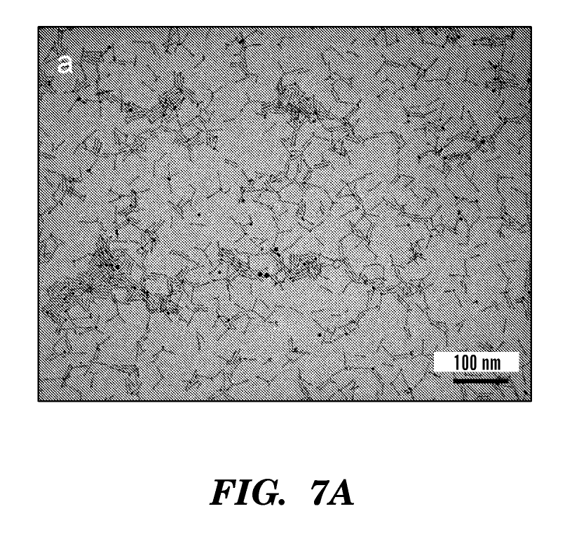

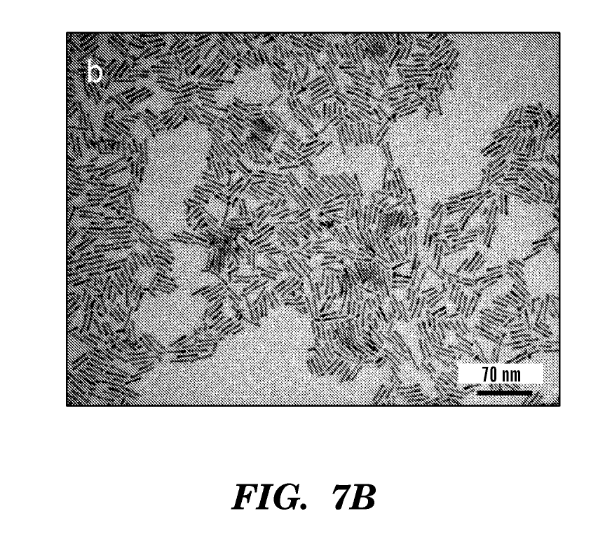

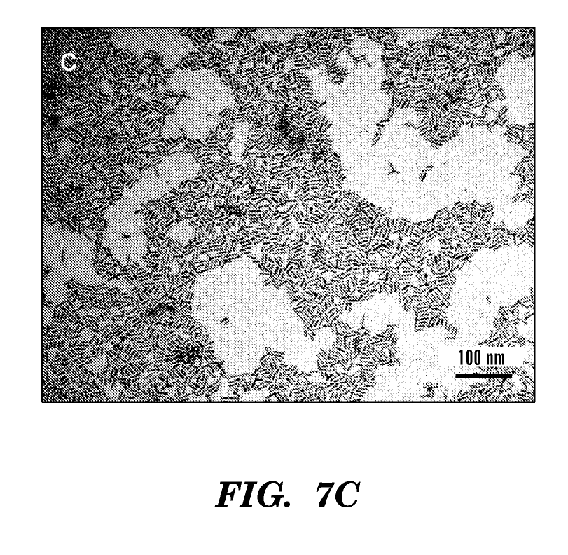

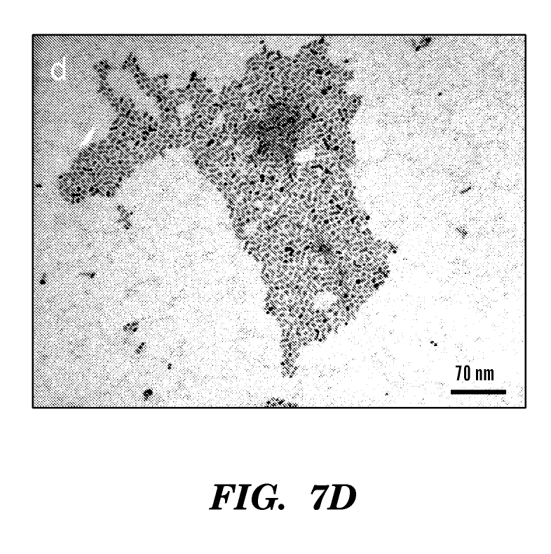

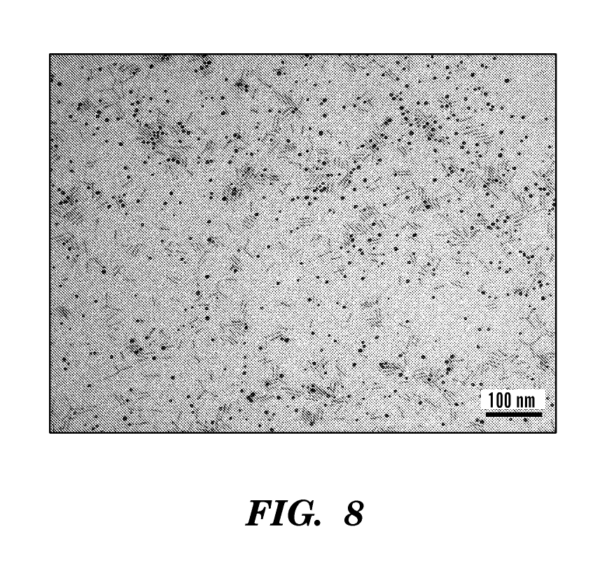

FIGS. 7A-D present TEM images of the quantum rods of CdSe(Au), CdSe(Ag), CdSe(Pd), and CdSe(Pt) nanocrystals, respectively, from samples withdrawn after a longer reaction time (15-25 minutes). The quantum rods have lengths of 33.0±6, 30.0±6.7, 20.0±5.2, and 8.0±4.7 nm and diameters of 2.7±0.3, 3.0±0.3, 3.4±0.4, and 3.5±0.3 nm, respectively. The aspect ratio decreased slowly with increasing heating time, up to 40 minutes. Comparing FIGS. 5A-E and FIG. 7D, it is seen that the aspect ratio of the CdSe(Pt) rods decreased from 3.7 after 3 minutes to 2.2 after 20 minutes. This suggests that further heating after depletion of the Cd-myristic acid precursor complex results in ripening of the nanorods that would eventually reshape them into spheres. However, at the low reaction temperature used, this process is relatively slow. Such ripening was not observed at room temperature, where particle aspect ratios were stable for months. After reaction was complete, the noble metal particles had detached from the rods (FIG. 8) and could be easily separated from the mixture through selective precipitation and centrifugation.

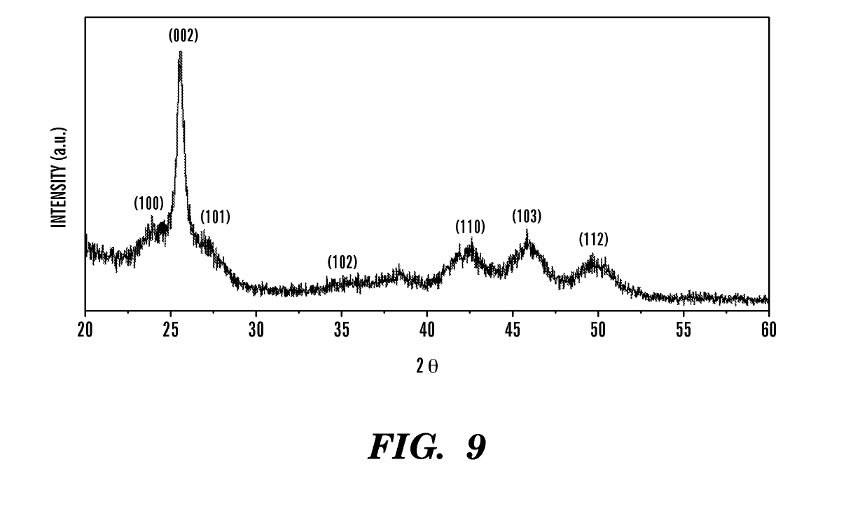

High-resolution transmission electron microscopy (FIGS. 6E-F) and powder X-ray diffraction (XRD) (FIG. 9), confirmed that the growth axis of the rods was the c-axis of the wurtzite structure. The powder x-ray diffraction pattern of the CdSe quantum rod sample, with Au seeding, is shown in FIG. 9. The diffractogram has the hexagonal wurtzite (100), (002), and (101) peaks of CdSe, with a dominant (002) peak (Kong et al., “Nanotube Molecular Wires as Chemical Sensors,” Science 287:622-625 (2000), which is hereby incorporated by reference in its entirety) that is much less broadened than the other peaks, indicating longer-range order in that direction. No peaks due to Au are present, because a negligible amount of Au remains in the rod-like structures.

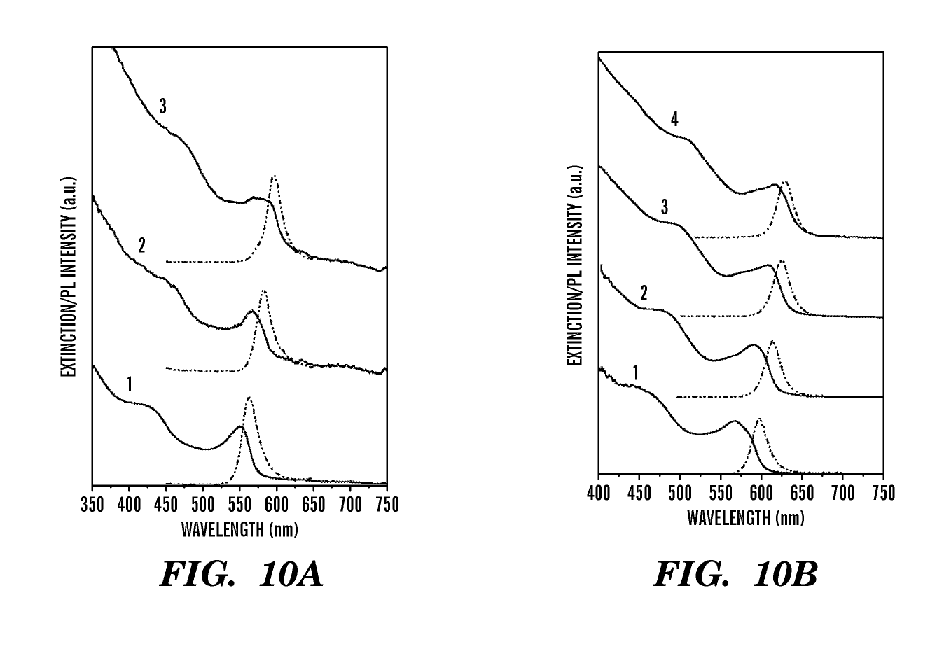

Absorption spectra of the multipods (FIG. 10A) and rods (FIG. 10B) of all the nanocrystals show the expected structure with absorption onsets of 566, 589, 607, and 615 nm for CdSe(Au), CdSe(Ag), CdSe(Pd), and CdSe(Pt) nanorods, respectively. The absorption onset red shifts with increasing rod diameter, and the emission Stokes shift increases with increasing aspect ratio, as expected for quantum rods. The photoluminescence (PL) quantum yields of the CdSe(Au), CdSe(Ag), CdSe(Pd), and CdSe(Pt) quantum rods were 2.7, 10.9, 7.3, and 8.8%, respectively. These quantum yields are much higher than the previously reported values for CdSe quantum rods. The quantum yield could probably be further improved by depositing a shell of a larger-band gap material (CdS or ZnS) on the quantum rod, as shown previously (Manna et al., “Epitaxial Growth and Photochemical Annealing of Graded CdS/ZnS Shells on Colloidal CdSe Nanorods,” J. Am. Chem. Soc. 124:7136 (2002), which is hereby incorporated by reference in its entirety).

Metal particles have been used to induce one-dimensional nanocrystal growth in other systems including CdSe and PbSe with Bi/Au core/shell material (Grebinski et al., “Synthesis and Characterization of Au/Bi Core/Shell Nanocrystals: A Precursor toward II-VI Nanowires,” J. Phys. Chem. B. 108:9745-9751 (2004); Hull et al., “Induced Branching in Confined PbSe Nanowires,” Chem. Mater. 17:4416-4425 (2005), which are hereby incorporated by reference in their entirety), InAs with Au, Ag, or In (Kan et al., “Synthesis and Size-Dependent Properties of Zinc-Blende Semiconductor Quantum Rods,” Nat. Mater. 2:155-158 (2003); Kan et al., “Shape Control of III V Semiconductor Nanocrystals: Synthesis and Properties of InAs Quantum Rods,” Faraday Discuss. 125:23 (2004), which are here by incorporated by reference in their entirety), and Si and Ge with Au (Holmes et al., “Control of Thickness and Orientation of Solution-Grown Silicon Nanowires,” Science 287:1471-1473 (2000); Hanrath et al., “Nucleation and Growth of Germanium Nanowires Seeded by Organic Monolayer-Coated Gold Nanocrystals,” J. Am. Chem. Soc. 124:1424-1429 (2002), which are hereby incorporated by reference in their entirety). In these cases, the growth is believed to occur via the SLS mechanism, first proposed by Trentler et al., “Solution-Liquid-Solid Growth of Crystalline III-V Semiconductors: An Analogy to Vapor-Liquid-Solid Growth,” Science 270:1791-1794 (1995), which is hereby incorporated by reference in its entirety, in which the metal nanoparticles melt and serve as nucleation sites where a supersaturated precursor solution is converted into a crystalline product. The material being synthesized, or one of its components, dissolves in the droplet and is expelled at a single point in the form of a nanorod or nanowire. Simultaneous growth might occur at multiple points on the metal nanoparticle surface, giving rise to a heterogeneous multipod. In addition, the zincblende crystal structure may nucleate on the surface of the metal particle itself, followed by growth of wurtzite arms from the (111) faces of this nucleus, resulting in a homogeneous multipod (bipod, tripod, or tetrapod).

In the method of the present invention, particles of Au, Ag, Pd, and Pt with bulk melting temperatures of 1064, 962, 1554 and 1768° C., respectively, have been employed at temperatures below 225° C. The formation of quantum rods is observed in all cases, indicating that something like the SLS mechanism is operative even at this temperature. However, it is highly unlikely that the seed particles are molten at the temperatures used here. Even accounting for size-dependent melting point depression (Dick et al., “Size Dependent Melting of Silica-Encapsulated Gold Nano-Particles,” J. Am. Chem. Soc. 124:2312-2317 (2002), which is hereby incorporated by reference in its entirety), temperatures above 700° C. should be required to melt 4 nm gold seed particles. Significant quantities of cadmium can dissolve in the noble metals, and this alloying would also lower the melting point (Baker et al., ASM handbook: Alloy Phase Diagrams, Materials Park, Ohio: ASM International, 1992, which is hereby incorporated by reference in its entirety). However, complete melting at 220° C. remains unlikely. Some molecular dynamics simulations of small metal clusters suggest that before the onset of melting, the relatively loosely bound surface atoms can undergo a surface-melting transformation (Cleveland et al., “Melting of Gold Clusters,” Phys. Rev. B 60:5065-5077 (1999), which is hereby incorporated by reference in its entirety), which could make a SLS-type growth mechanism possible. Atomic surface and bulk diffusion coefficients are also size dependent, and are expected to be several orders of magnitude larger in these nanoparticles than in the bulk (Dick et al., “Size Dependent Melting of Silica-Encapsulated Gold Nano-Particles,” J. Am. Chem. Soc. 124:2312-2317 (2002), which is hereby incorporated by reference in its entirety). This could enable a solid-state diffusion mechanism like that proposed by Persson et al., “Solid-Phase Diffusion Mechanism for GaAs Nanowire Growth,” Nat. Mater. 3:677-681 (2004), which is hereby incorporated by reference in its entirety, for vapor-solid-solid growth of GaAs and InAs under conditions where the seed particles remain solid. Similarly, catalytically seeded growth of Si and Ge nanowires using solid seed particles has been reported to occur by a supercritical fluid-solid-solid mechanism (Hanrath et al., “Nucleation and Growth of Germanium Nanowires Seeded by Organic Monolayer-Coated Gold Nanocrystals,” J. Am. Chem. Soc. 124:1424-1429 (2002); Tuan et al., “Germanium Nanowire Synthesis: An Example of Solid-Phase Seeded Growth with Nickel Nanocrystals,” Chem. Mater. 17:5705-5711 (2005); Tuan et al., “Catalytic Solid-Phase Seeding of Silicon Nanowires by Nickel Nanocrystals in Organic Solvents,” Nano Lett 5:681-684 (2005), which are hereby incorporated by reference in their entirety).

In the method of the present invention, if the seed particle remains crystalline, then the rod growth may occur on particular crystal faces for which pseudo-epitaxial growth is possible, as shown schematically in FIGS. 1A-B. Because the lattice matching between the seed and the rod is only approximate, this pseudo-epitaxy is possible only over a small rod diameter. This would explain the lack of correlation between the rod diameter and the seed particle diameter. In fact there is some limited correlation of the rod diameter with the lattice constant of the seed particle; Ag and Au, with lattice constants of 4.09 and 4.08 Å, respectively, produce somewhat smaller diameter rods than Pd and Pt, with lattice constants of 3.89 and 3.92 Å, respectively. This pseudo-epitaxial growth could also lead to the observed cleavage of the nanocrystal from the seed particle, since the crystal strain energy in the growing nanocrystal, due to lattice mismatch, would increase with nanorod length. When this total strain energy exceeds a critical value, it will be thermodynamically favorable for the rod to cleave from the seed particle, relieving this strain at the expense of creating new interfaces.

The above data show that pure noble metal nanoparticles can seed anistropic growth of high quality Group II-VI nanocrystals at lower temperature and reagent concentrations than have been used in other methods of preparing anisotropic Group II-VI structures. The resulting nanocrystals have unusually high photoluminescence quantum yields. The ability to easily produce high quality nanocrystals in high yield and to control their shape in this way will be valuable in spectroscopic studies and in applications such as bioimaging technologies, light-emitting diodes (LEDs), and photovoltaics. The above data provide a new direction in developing facile syntheses of semiconductor nanocrystals with nonspherical morphology, thereby making available new building blocks for nanotechnology.

### Example 6

### Materials and Methods

Lead oxide (PbO), oleic acid, selenium, trioctylphosphine, tetraoctylammonium bromide (98%), hydrogen tetrachloroaurate(III) trihydrate (HAuCl₄.3H₂O), palladium chloride (PdCl₂), sodium borohydride, dodecylamine, and phenyl ether were purchased from Sigma-Aldrich (St. Louis, Mo.). Silver nitrate (AgNO₃) was purchased from Alfa Aesar (Ward Hill, Mass.). All chemicals were used as received. All solvents (hexane, toluene, and acetone) were used without any further purification.

Au, Ag, and Pd nanoparticles were prepared as described above in Example 2.

### Example 7

### Synthesis of PbSe Nanocrystals

PbSe Quantum Rods

1.0 M stock solution of trioctylphosphine selenide (TOPSe) was prepared in advance by dissolving 7.86 g of selenium in 100 mL of TOP. 1 mmol of lead oxide, 0.1 mL of freshly prepared gold nanoparticles, and 2 mL of oleic acid were dissolved in 3 mL of phenyl ether. The reaction mixture was heated to 150° C. for ˜20-35 minutes under an argon flow. 1 mL of 1.0 M TOPSe solution was injected under gentle stirring into the hot (150° C.) reaction mixture. Aliquots from the reaction were removed every ˜30 seconds by a syringe and were injected into a large volume of toluene at room temperature, thereby quenching any further growth of the nanocrystals. The nanocrystals were separated from the toluene solution by addition of ethanol and centrifugation. The precipitated nanocrystals could be redispersed in various organic solvents (hexane, toluene, and chloroform) to form a dispersion that was stable for weeks. The reaction conditions for PbSe nanocrystals with different morphologies are summarized in Table 2.

TABLE 2
Reaction conditions for PbSe nanocrystals.

| | Pb:Se | Growth | | Shape/ | Dimension | Yield |
|---|---|---|---|---|---|---|
| | Ratio | Time | | Structure | (nm) | (%) |
| Au nano- | | | | | | |
| particles | | | | | | |
| mmol | | | | | | |
| ˜0.0005 | 1:1 | ˜30-45 | s | Rod | 24.4 ± 4.9^{a}, | ˜90 |
| | | | | | 5.7 ± 0.8^{b}, | |
| | | | | | 4.3 ± 0.2^{c} | |
| ˜0.0005 | 1:1 | ˜1-1 | min | Rod | 32.6 ± 6.5^{a}, | ˜90 |
| | | 30 | s | | 6.5 ± 1.0^{b}, | |
| | | | | | 5.0 ± 1.0^{c} | |
| ˜0.0005 | 1:1 | ˜3-4 | min | Rod | 44.3 ± 6.3^{a}, | ˜90 |
| | | | | | 9.8 ± 0.7^{b}, | |
| | | | | | 4.5 ± 0.9^{c} | |
| ˜0.0005 | 2:1 | ˜1 | min | Cube | 8.1 ± 1.6^{d} | ˜90 |
| ˜0.0005 | 1:2 | ˜2 | min | T-shape | — | ˜60 |
| ˜0.0005 | 3:1 | ˜2 | min | Dots | 5.5 ± 0.7 | ˜100 |
| ˜0.005 | 1:1 | ˜1 | min | Cross | 31.6 ± 5.1^{e} | ˜85 |
| ˜0.025 | 1:1 | ˜1 | min | Core- | 7.3 ± 0.8 | ˜95 |
| | | | | shell | | |
| Ag nano- | | | | | | |
| particles/ | | | | | | |
| mmol | | | | | | |
| ˜0.0005 | 1:1 | ˜1 | min | Diamond | 10.7 ± 2.7 | ˜90 |
| ˜0.025 | 1:1 | ˜1 | min | Branched | — | ˜95 |
| Pd nano- | | | | | | |
| particle/ | | | | | | |
| mmol | | | | | | |
| ˜0.0005 | 1:1 | ˜1 | min | Star | — | ˜90 |
| ˜0.025 | 1:1 | ˜1 | min | Quasi- | 4.1 ± 0.8 | ˜90 |
| | | | | spherical | | |

^{a}Rod length,
^{b}rod width and
^{c}aspect ratio.
^{d}For cubes, this corresponds to edge lengths.
^{e}For cross and diamond profile, this corresponds to the distance between opposite sides.

PbSe Nanocrosses

PbSe nanocrosses were prepared following the same procedure described above for PbSe quantum rods, except that ˜0.005 mmol of gold nanoparticles was used instead of 0.0005 mmol.

Core-Shell Gold-PbSe Nanocrystals

Core-shell gold-PbSe nanostructures were synthesized following the same procedure described above for PbSe quantum rods, except that ˜0.25 mmol of gold nanoparticles was used, instead of ˜0.0005 mmol.

PbSe Nanocubes

Cubic PbSe nanocrystals were prepared following the same procedure described above for PbSe quantum rods, except that a 2:1 Pb:Se ratio was used instead of 1:1 (doubling the amount of Pb precursor).

T-Shape PbSe Nanocrystals

T-shaped PbSe nanocrystals were synthesized following the same procedure described above for PbSe quantum rods, except that a 1:2 Pb:Se ratio was used instead of 1:1 (doubling the amount of Se used).

PbSe Quantum Dots

PbSe quantum dots were prepared following the same procedure described above for PbSe quantum rods, except that a 3:1 Pb:Se ratio was used instead of 1:1 (tripling the amount of Pb precursor).

Diamond-Shape PbSe Nanocrystals

Diamond-shaped PbSe nanocrystals were synthesized using the same procedure described above for PbSe quantum rods, except that ˜0.0005 mmol of silver nanoparticles was used instead of gold nanoparticles.

Branched PbSe Nanocrystals

Branched PbSe nanocrystals were prepared using the same procedure described above for PbSe quantum rods, except that the ˜0.25 mmol of silver nanoparticles was used instead of gold nanoparticles.

Star-Shaped PbSe Nanocrystals

Star-shaped PbSe nanocrystals were synthesized using the same procedure described above for PbSe quantum rods, except that the ˜0.0005 mmol of palladium nanoparticles was used instead of gold nanoparticles.

Quasi-Spherical PbSe Nanocrystals

Quasi-spherical PbSe nanocrystals were prepared using the same procedure described above for PbSe quantum rods, except that the ˜0.025 mmol of palladium nanoparticles was used instead of gold nanoparticles.

### Example 8

### Characterization of PbSe Nanocrystals

Transmission Electron Microscopy, High-Resolution Transmission Electron Microscopy, and X-ray Diffraction of PbSe nanocrystals was performed as described above in Example 5.

Among the IV-VI semiconductors, the PbSe nanocrystals constitute an interesting system because of the ease of realizing quantum modulated optical behavior in the infrared range. Because of the large Bohr exciton radius in PbSe (about 46 nm), quantum confinement effects begin to appear at relatively large particle dimensions. Bulk PbSe has a rock salt crystal structure and is a direct gap semiconductor with a band gap of 0.28 eV. Solution processible PbSe nanocrystals exhibit well-defined band-edge excitonic transitions tunable between 0.9 and 2.0 eV and small Stokes shifts (Du et al., “Optical Properties of Colloidal PbSe Nanocrystals,” Nano Lett 2:1321-1324 (2002); Wehrenberg et al., “Interband and Intraband Optical Studies of PbSe Colloidal Quantum Dots,” J. Phys. Chem. B. 106:10634-10640 (2002), which are hereby incorporated by reference in their entirety). They have been shown to be efficient photo-charge generators at communication IR wavelengths (Choudhury et al., “Ultra Efficient Photoconductive Device at Mid-IR Wavelengths from Quantum Dot-Polymer Nanocomposites,” Appl. Phys. Lett 87:073110-1-073110-3 (2005), which is hereby incorporated by reference in its entirety). Furthermore, they have been suggested as an effective system for deep tissue imaging (Lim et al., “Selection of Quantum Dot Wavelengths for Biomedical Assays and Imaging,” Mol Imaging 2:50-64 (2003), which is hereby incorporated by reference in its entirety).

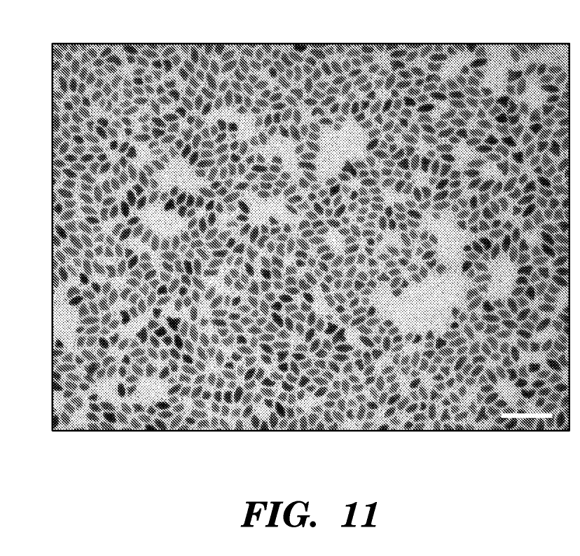

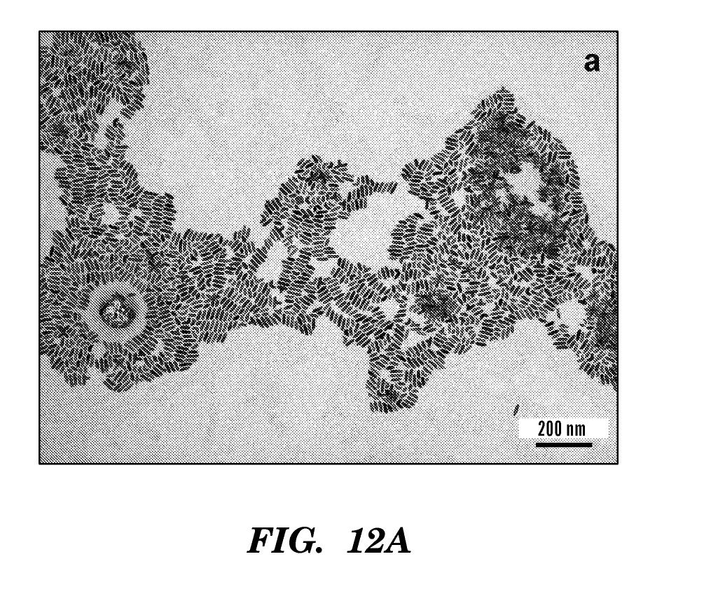

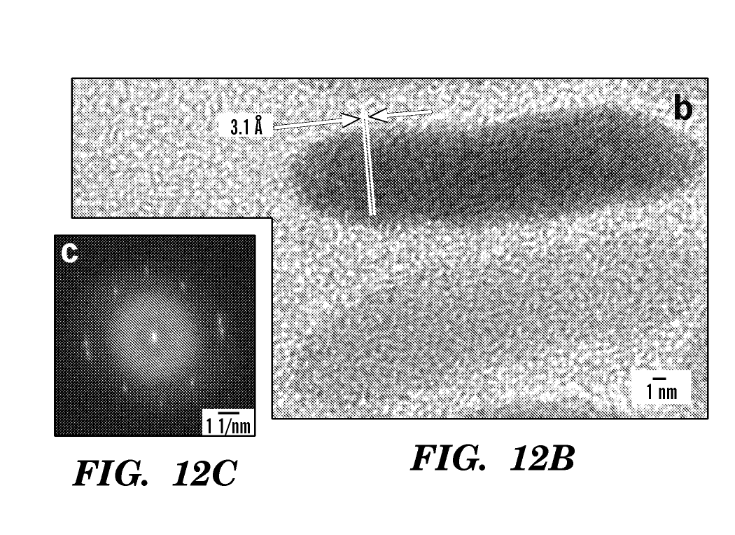

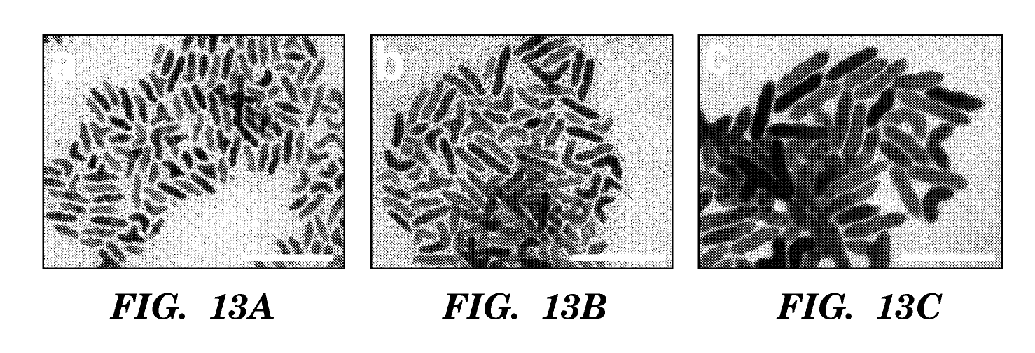

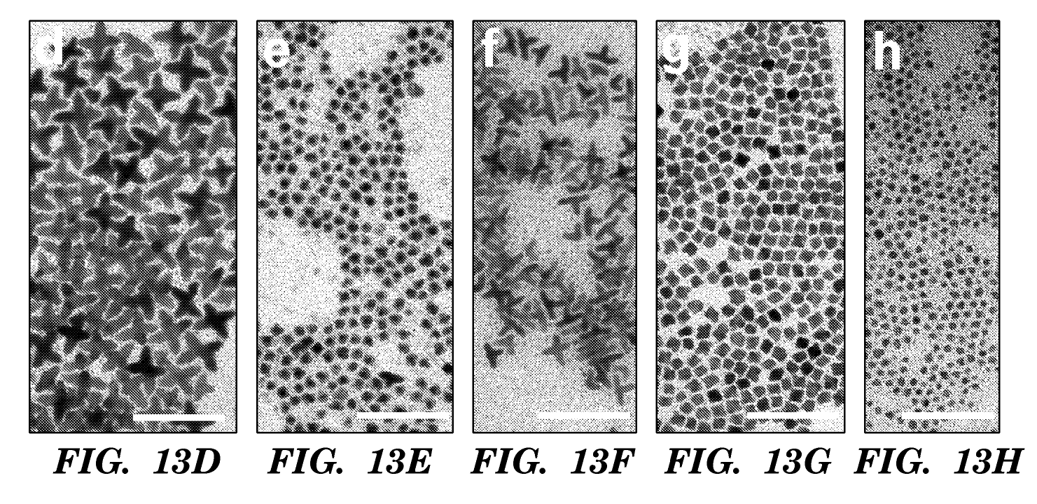

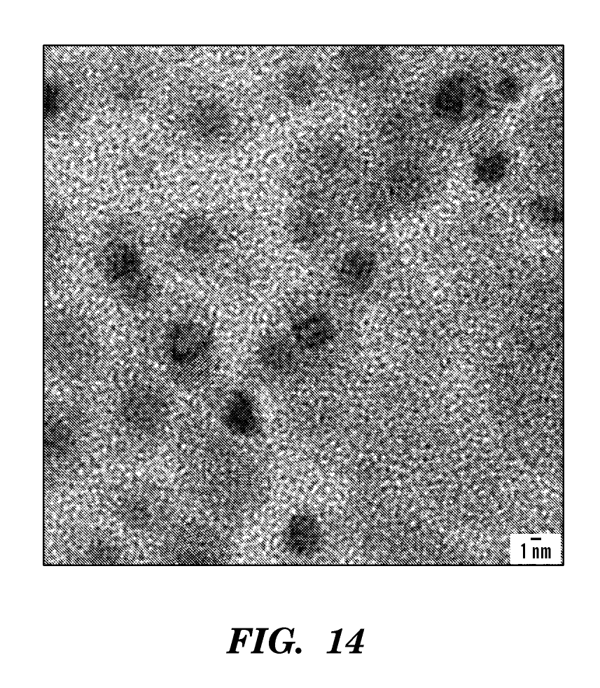

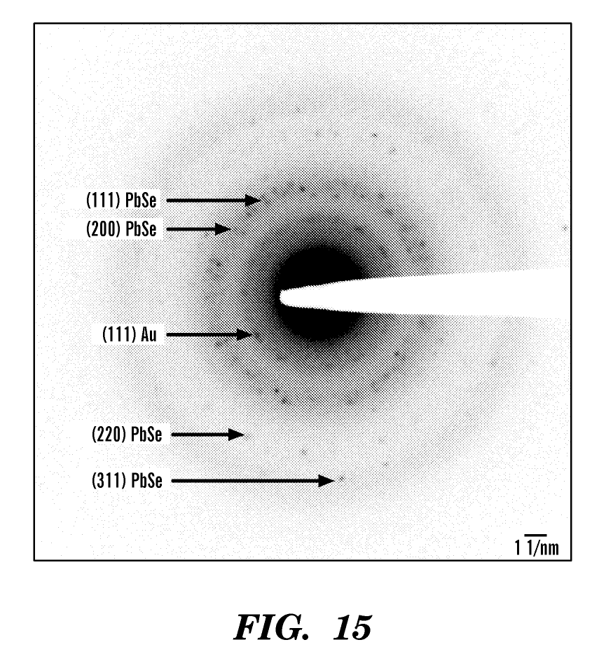

The most important parameter in determining the shape, size, and structure of PbSe nanocrystals, according to the method of the present invention, is the concentration of the metal nanoparticles, followed by the Pb:Se precursor ratio. The dimensions and structure of the PbSe nanocrystals change significantly as the metal concentration is changed. In the absence of any metal seed particles, slightly anisotropic ovoid or diamond-shaped nanocrystals were formed, with an aspect ratio of about 1.5 (FIG. 11). At low concentration of gold nanoparticles (˜0.0005 mmol metal atoms and a Pb:Se ratio of 1:1) quantum rods, T-shaped, and L-shaped particles were formed, with quantum rods constituting the vast majority (>90%) (FIG. 12A). As shown in FIG. 13A, at an early stage (i.e. within the first 30 to 45 seconds) of the reaction, the rod length was relatively small, but it progressively increased with the growth time (FIGS. 13B-C). However, the aspect ratio of the rods remained roughly constant. When the gold nanoparticle concentration was increased to ˜0.005 mmol metal atoms, no PbSe quantum rods were formed; instead, cross-shaped PbSe nanocrystals appeared (FIG. 13D). Upon further increase in the gold nanoparticle concentration to ˜0.0250 mmol metal atoms, gold core-PbSe shell structures appeared (FIG. 13E). High-resolution TEM and selected area electron diffraction clearly showed the presence of both Au and PbSe in these nanoparticles and confirmed the core-shell structure (FIG. 14 and FIG. 15). By changing the Pb:Se ratio from 1:1 to 2:1, 3:1, or 1:2, while maintaining the gold nanoparticle concentration at ˜0.0005 mmol metal atoms, T-, cube-, and dot-shaped particles were formed, respectively (FIGS. 13F-H).

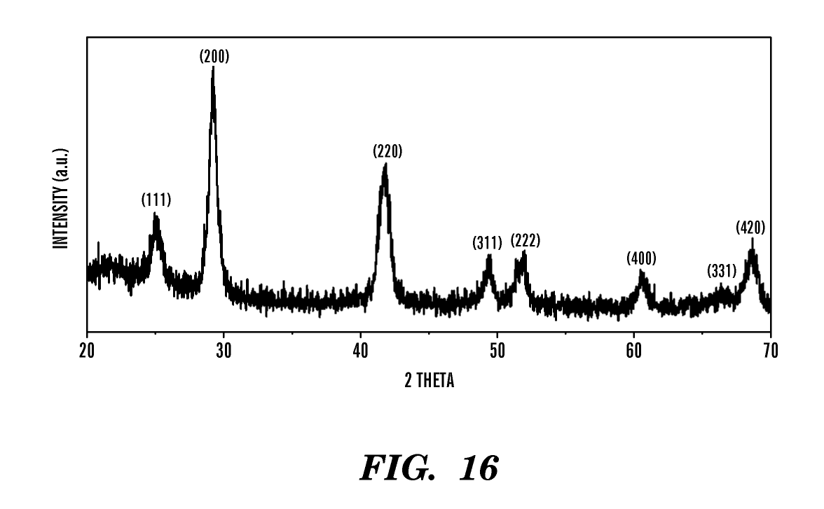

The XRD pattern of PbSe crystalline quantum rods is shown in FIG. 16. All the diffraction peaks correspond to the cubic rock-salt structure of PbSe. The (200) peak is less broadened than the others, indicating a longer-range order in that direction, which corresponds to the axis of the quantum rods. No discernible peaks of Au were observed, apparently because of the very small amount of Au used. The lattice fringes of the PbSe quantum rods are clearly shown in FIG. 12B, with fringe spacing of 3.1 Å. These fringes, which correspond to (200) lattice planes for the cubic rock salt structure of PbSe, are aligned perpendicular to the rod axis. This confirms that the quantum rod elongation axis was in the [100] direction. Both the XRD and the HRTEM results confirm that the long axis of the quantum rods corresponds to the [100] direction of the cubic rock salt structure.

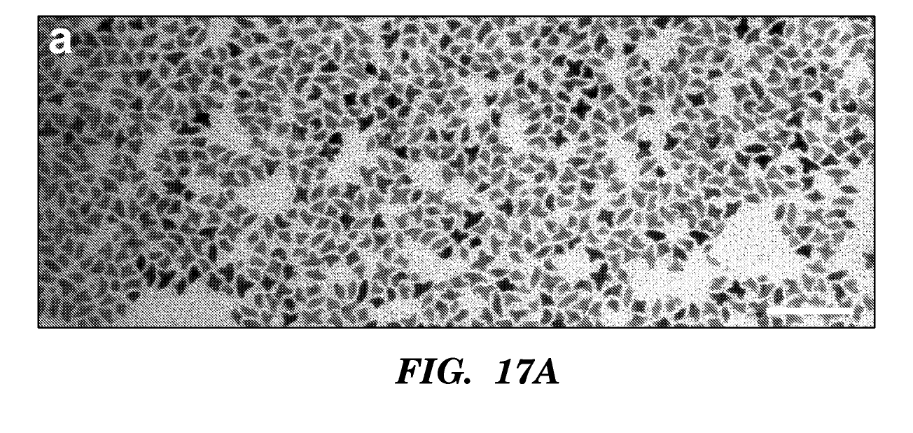

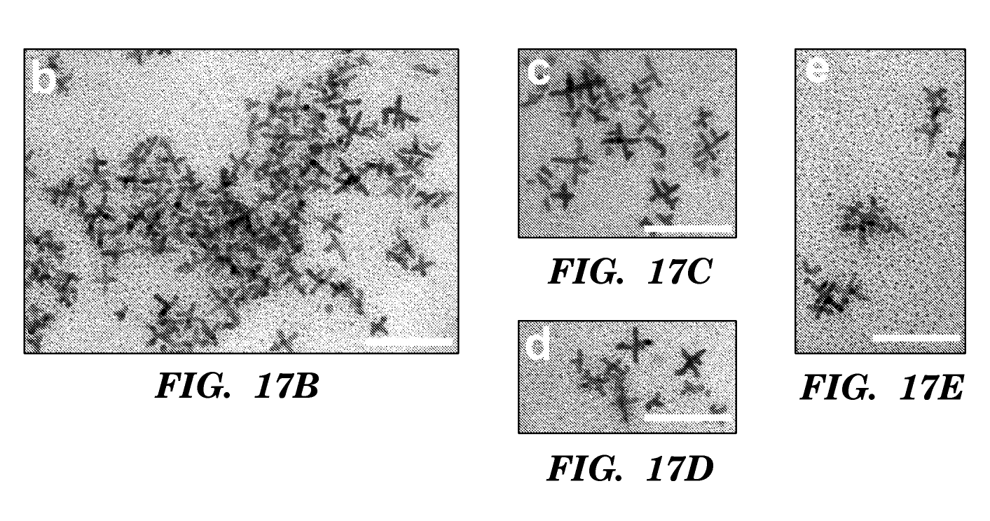

By using silver nanoparticles at low concentration (˜0.0005 mmol metal atoms), a high yield (approximately 90% of the nanocrystal population) of diamond-shaped PbSe nanocrystals was obtained (FIG. 17A). When the reaction was performed at a higher concentration of Ag nanoparticles (˜0.025 mmol metal atoms), multi branched crystals were formed (FIGS. 17B-E). Notably, no freestanding discrete rods were observed, in contrast to the synthesis using the same concentration of Au nanoparticles. Since the silver nanoparticles are larger than the gold ones used here, an equal metal atom concentration corresponds to a seed particle number concentration that is about a factor of 5 smaller for silver than for gold. At this very low seed particle concentration, there may be a significant number of ‘unseeeded’ PbSe nanocrystals formed, and indeed some of the particles observed here are similar to those observed in the absence of metal seeds. However, there is still an effect of the metal nanoparticles on the morphology of most of the nanocrystals.

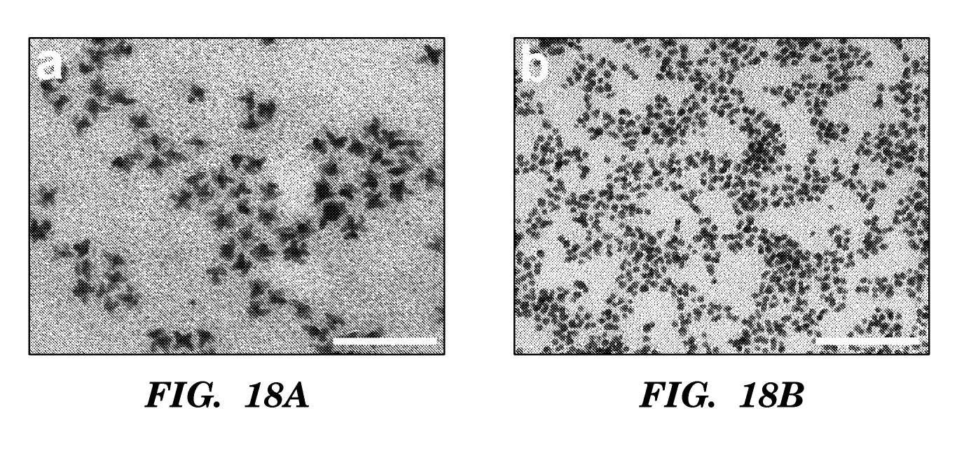

When Pd nanoparticles were used as the seeds at a level of ˜0.0005 mmol metal atoms, star-shaped PbSe nanocrystals were formed (FIG. 18A). The yield of the star-shaped particles was as high as ˜90% of the nanocrystal population. By further increasing the concentration to ˜0.025 mmol, quasi-spherical PbSe nanocrystals were obtained (FIG. 18B).

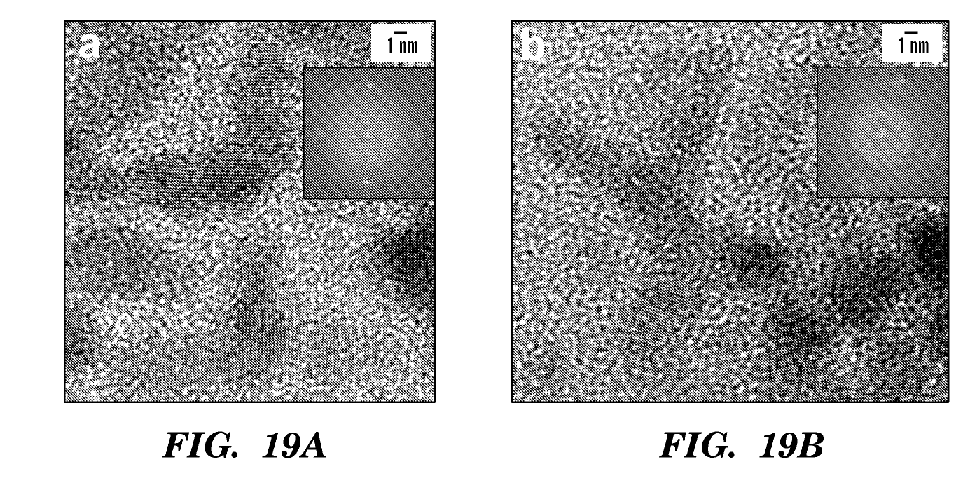

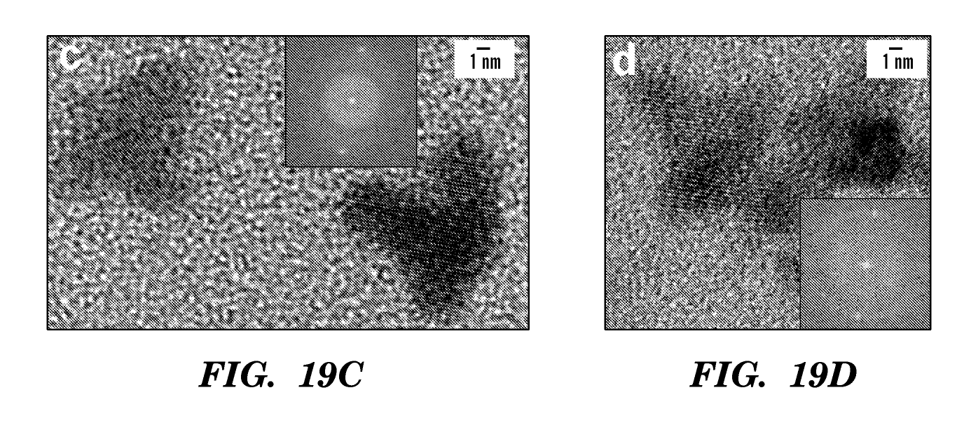

FIGS. 19A-D show HRTEM images of highly crystalline T-shaped, multi-branched, diamond-shaped, and star-shaped PbSe nanocrystals. These also show lattice fringes of the cubic PbSe lattice. The T-shaped, multi-branched, and diamond-shaped PbSe nanocrystals have fringe spacing of 3.1 Å, which corresponds to (200) lattice planes for the cubic rock salt structure of PbSe. However, the star-shaped PbSe nanocrystals have fringe spacing of 3.6 Å, corresponding to the PbSe (111) planes. For the branched structures shown in FIGS. 19A-C, two perpendicular sets of (200) planes are visible, as also reflected in the Fourier transforms of these images. As for the unbranched (simple) rods, the growth direction for each branch of these is the [100] direction. This constrains the branches to be at ˜90 degree angles from each other. It appears from the HRTEM that the PbSe quantum rods synthesized in this work are solid rods and are not a fused string of individual PbSe nanocrystals as reported by Cho et al., “Designing PbSe Nanowires and Nanorings Through Oriented Attachment of Nanoparticles,” J. Am. Chem. Soc. 127:7140-7147 (2005), which is hereby incorporated by reference in its entirety). Additionally, it is noted that the width of PbSe quantum rods shown in FIGS. 12A-C is smaller than the Bohr exciton radius in PbSe (46 nm). The electrons and holes in the quantum rods should be strongly quantum confined.

The formation of various shapes of PbSe nanocrystals must result from changes in the PbSe nanocrystal nucleation and growth kinetics in the presence of the metallic nanoparticles. Most previous studies of metal-seeded solution-phase growth of crystalline semiconductor nanowires and nanorods have been interpreted in terms of the solution-liquid-solid mechanism proposed by Trentler et al., “Solution-Liquid-Solid Growth of Crystalline Ill-V Semiconductors: An Analogy to Vapor-Liquid-Solid Growth,” Science 270:1791-1794 (1995), which is hereby incorporated by reference in its entirety. In the present experiments, however, the metallic seed particles are probably not molten under the growth conditions. Even accounting for the size-reduction of the melting point (Dick et al., “Size Dependent Melting of Silica-Encapsulated Gold Nano-Particles,” J. Am. Chem. Soc. 124:2312-2317 (2002), which is hereby incorporated by reference in its entirety), temperatures above 700° C. are required to melt 4 nm gold particles like those used as seeds here. The Au—Pb phase diagram (Smithells Metals Reference Book; 7 ed.; Brandes et al., Eds.; Elsevier (1998), which is here by incorporated by reference in its entirety) shows that lower melting point solutions can form, down to the AuPb₂—Pb eutectic temperature of 215° C., but this requires the formation of metallic lead and intermetallic compounds. In control experiments in which the selenium precursor was omitted, no metallic lead or Au—Pb intermetallic compounds formed. Thus, it is most likely that the PbSe growth is catalyzed not by a liquid metal droplet, but by a metal nanocrystal. The seed nanocrystal may have a quasi-molten surface layer, as has been predicted by some molecular dynamics simulations of metal nanocrystal melting (Cleveland et al., “Melting of Gold Clusters,” Phys. Rev. B 60:5065-5077 (1999); Cleveland et al., “Melting of Gold Clusters: Icosahedral Precursors,” Phys. Rev. Lett 81:2036-2039 (1998); Miao et al., Phys. Rev. B 72:134109 (2005), which is hereby incorporated by reference in its entirety). Solid-state diffusion of Pb or Se within the metal seed particles is also unlikely, since the solubility of both Pb and Se in the noble metals is very small (at least in the bulk) (Smithells Metals Reference Book, 7 ed.; Brandes et al., Eds.; Elsevier (1998), which is here by incorporated by reference in its entirety). Thus, it is expected that the essential contribution of the seed particle is simply to provide a low energy interface for heterogeneous nucleation of the PbSe nanocrystal. It is hypothesized that, initially, one or more PbSe rods nucleate on each seed particle, and that when the rod length exceeds a critical value, it detaches from the nucleation site. This would be expected to occur when the total internal crystal strain energy due to lattice mismatch between the metal and PbSe becomes sufficiently large as the length of the rod increases. The mechanism of formation of branched structures may be similar to the geminate nanowire nucleation mechanism proposed by Kuno and co-workers (Hull et al., “Induced Branching in Confined PbSe Nanowires,” Chem. Mater. 17:4416-4425 (2005); Grebinski et al., “Solution Based Straight and Branched CdSe Nanowires,” Chem. Mater. 16:5260-5272 (2004), which are hereby incorporated by reference in their entirety). If multiple rods are growing simultaneously from a single seed crystal, they may merge to produce branched structures, prior to being cleaved from the seed nanocrystal.

In support of the concept that multiple rods are seeded by each noble metal particle, it is estimated that the ratio of the number of rods produced to the number of seed particles is as follows. A 4 nm diameter Au sphere has a volume of ˜3.4×10⁻²⁰ cm³, a mass of ˜6.5×10⁻¹⁹ g, and contains ˜2000 atoms. For nanorod synthesis, the total amount of gold used was ˜5×10⁻⁷ mol, corresponding to ˜1.5×10¹⁴ Au nanoparticles. Comparing this to the 1 mmol of Pb and Se precursors used, there is about 4×10⁶ precursor molecules per seed particle. The yield of particles was determined gravimetrically in an experiment that produced rods with an average diameter of 8.5 nm and average length of 32.5 nm, as determined from manual counting and measurement of TEM images. The mass of recovered particles, after three cycles of washing with ethanol, precipitation, and centrifugation, was 18.2 mg. Thermogravimetric analysis showed an additional 35% weight loss assignable to the organic surfactant components. Thus, a final yield of ˜11.8 mg of product was obtained. This corresponds to ˜4% of the maximum theoretical yield of 286.2 mg from 1 mmol of each precursor, but the actual yield may have been significantly higher since losses are likely during the multiple washing steps. A PbSe rod 8.5 nm in diameter by 32.5 nm long has a volume of ˜1.8×10¹⁸ cm³, a mass of 1.5×10⁻¹⁷ g, and contains ˜32000 atoms each of Pb and Se. If each nanoparticle generated only a single rod of this size, then the yield of PbSe would be only about 32000/4000000=0.8%. This is a factor of 5 smaller than the measured lower limit of the PbSe yield. Therefore, on average, several rods must be produced per seed particle. This, in turn, requires that the rods cleave from the seed particles, since individual rods are observed in the final products.

The estimates in the preceding paragraph suggest that for conditions that result in formation of simple (unbranched) rods, the precursors are not significantly depleted in the reaction times used here (up to ˜4 minutes). From the results shown in FIGS. 13A-C, it also appears that the rods continue to grow anisotropically after cleaving from the seed particles. For that experiment, the aspect ratio of the rods remained nearly constant as the rods roughly doubled in both length and diameter and maintained their simple rod morphology. Significantly longer reaction times led to precipitation of large agglomerates, which also supports the suggestion that substantial precursor remains in the reactor after these short reaction times. For higher seed particle concentrations, substantial precursor depletion may have occurred. Since the local concentration of precursor around each seed particle is, initially, independent of the total number of seed particles, one would expect the initial nucleation to be independent of the seed particle concentration. However, when the seed particle concentration is increased by an order of magnitude from that used in the estimates above, then the same number of nucleation sites per particle would lead to substantial precursor depletion. This, in turn, would slow the growth rate, allowing more time for the rods growing from a given seed to align and fuse together, producing T- or cross-shaped particles like those shown in FIG. 13D. Further increases in the seed particle concentration could result in complete depletion of precursors prior to cleavage of the rods from the seed particles. This would lead to core-shell particles with rough polycrystalline shells (resulting from multiple nucleation sites) like those shown in FIG. 13E and FIG. 14. Similarly, differences in nucleation and growth kinetics on the different metals used as seeds and for different precursor ratios could account for the varying propensity for formation of branched vs. simple rods, in the context of competition between growth to the point where the nanocrystal cleaves from the seed vs. alignment and merger of multiple rods growing from a single seed.

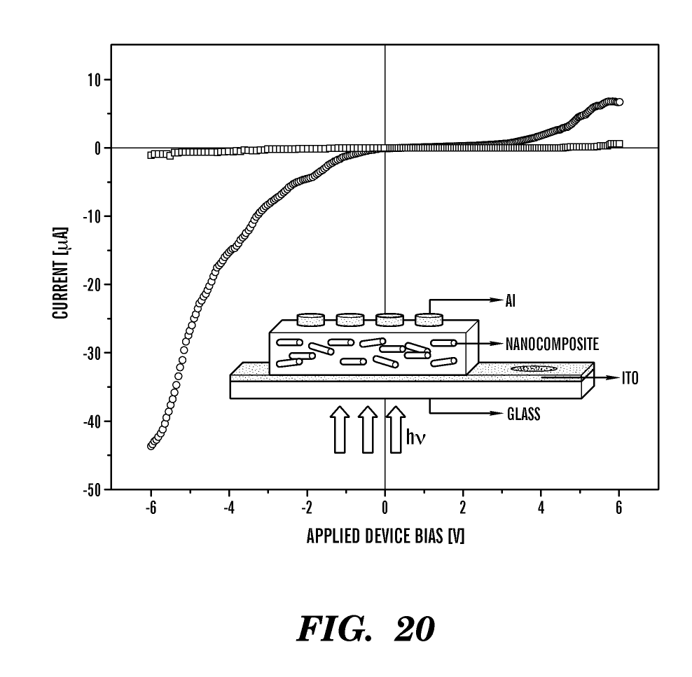

To demonstrate an application of these nanostructures in optoelectronic devices, composite photodetectors containing the PbSe quantum rods (length: 21 nm, diameter: 5.5 nm) and a photoconductive polymer (poly-N-vinylcarbazole (PVK)) were fabricated, as shown schematically in the inset of FIG. 20. Previous studies have shown that PbSe quantum dots incorporated into such polymeric composites can provide efficient photodetection at IR wavelengths (Choudhury et al., “Ultra Efficient Photoconductivity Device and Mid-IR Wavelengths from Quantum Dot-Polymer Nanocomposites,” Appl. Phys. Lett 87:073110-1-073110-3 (2005), which is hereby incorporated by reference in its entirety). Despite the lack of any distinct maximum in the absorption spectrum of the quantum rods, which might be due to the convolution of absorption peaks at several wavelengths from rods of different dimensions, the nanorods successfully photosensitize the polymer at an IR wavelength. FIG. 20 shows the current-voltage (I-V) behavior of this device in the presence and absence of 1.34 μm infrared light. Both I-V curves show nonlinear behavior, with the photo current more than an order of magnitude larger than the dark current. The photocurrent response corresponds to a photogeneration quantum efficiency of ˜0.25% at the highest operational bias for ˜200 nm thick samples. Judicious tailoring of the nanocrystal dimensions and optimized device compositions are expected to enhance the photogeneration efficiency at the desired operating wavelength, leading to much better photoconductive performance.

As set forth supra, the present invention is directed to a facile hot colloidal metallic seed-mediated method, which provides control of the shape, size and structure of nanocrystals by manipulating the type of noble metal nanoparticles and synthesis parameters. Nanocrystals of various shapes, including cylinders, cubes, crosses, stars, and branched structures were produced in high yield at a relatively low temperature within the first few minutes after the start of the synthesis. The optical absorption and luminescence of these multipod structures are similar to that of the corresponding quantum dots, though with a lower quantum efficiency as expected due to reduced quantum-confinement effects. Preliminary studies indicate that the nanocrystals obtained pursuant to the methods of the present invention can successfully be integrated into solution-processed, high-performance, large-area photoconductive devices.

Although preferred embodiments have been depicted and described in detail herein, it will be apparent to those skilled in the relevant art that various modifications, additions, substitutions, and the like can be made without departing from the spirit of the invention and these are therefore considered to be within the scope of the invention as defined in the claims which follow.

What is claimed:

1. A method of making non-spherical semiconductor nanocrystals, said method comprising:
providing a reaction mixture comprising a first precursor compound, a solvent, and a surfactant, wherein the first precursor compound comprises a Group II or a Group IV element;
contacting the reaction mixture with a pure noble metal nanoparticle seed;
heating the reaction mixture; and
adding a second precursor compound comprising a Group VI element to the heated reaction mixture under conditions effective to produce non-spherical semiconductor nanocrystals.

2. The method according to claim 1, wherein the first precursor compound comprises a Group II element.

3. The method according to claim 2, wherein the Group II element is selected from the group consisting of cadmium and zinc.

4. The method according to claim 3, wherein the Group II element is cadmium.

5. The method according to claim 2, wherein said heating is carried out to a temperature of about 200-260° C.

6. The method according to claim 1, wherein the first precursor compound comprises a Group IV element.

7. The method according to claim 6, wherein the Group IV element is lead.

8. The method according to claim 7, wherein the Group IV element is lead.

9. The method according to claim 6, wherein said heating is carried out to a temperature of about 130-170° C.

10. The method according to claim 1, wherein the Group VI element is selected from the group consisting of selenium and sulfur.

11. The method according to claim 10, wherein the Group VI element is selenium.

12. The method according to claim 1, wherein the pure noble metal nanoparticle seed is selected from the group consisting of gold, silver, palladium, and platinum.

13. The method according to claim 1, wherein said heating is carried out to a temperature below that at which the noble metal nanoparticle seed melts.

14. The method according to claim 1, wherein said non-spherical semiconductor nanocrystals comprise rods, multipods, and/or mixtures thereof.

15. The method according to claim 1 further comprising:
quenching the heated reaction mixture after said adding.

16. The method according to claim 15 further comprising:
washing and precipitating the reaction mixture after said quenching.

17. The method according to claim 1, wherein the first precursor compound is present in the reaction mixture at a concentration of about 0.06-0.2 mmol per ml reaction mixture.

18. A population of semiconductor nanocrystals comprising at least about 90% non-spherical nanocrystals.

19. The population of nanocrystals according to claim 18, wherein the nanocrystals are Group II-VI nanocrystals.

20. The population of nanocrystals according to claim 19, wherein the nanocrystals are CdSe nanocrystals.

21. The population of nanocrystals according to claim 18, wherein the nanocrystals are Group IV-VI nanocrystals.

22. The population of nanocrystals according to claim 21, wherein the nanocrystals are PbSe nanocrystals.

23. The population of nanocrystals according to claim 18, wherein the population has a quantum yield value of at least about 8-11%.

24. The population of nanocrystals according to claim 18, wherein the non-spherical nanocrystals comprise rods, multipods, and/or mixtures thereof.

25. The population of nanocrystals according to claim 18, wherein the non-spherical nanocrystals comprise T-shaped, multi-branched, diamond-shaped, and/or star-shaped nanocrystals.

26. The population of nanocrystals according to claim 18 comprising at least about 95% non-spherical nanocrystals.

27. The population of nanocrystals according to claim 18, wherein the non-spherical nanocrystals have an aspect ratio of about 2 to about 12.
